(19) United States
(12) Patent Application Publication
(10) Pub. No.: US 2025/0103777 A1
(43) Pub. Date: Mar. 27, 2025

(54) METHODS AND SYSTEMS FOR INTELLIGENT FIELD DEVELOPMENT AND OPTIMIZED PLACEMENT OF WELL PADS IN UNCONVENTIONAL AND CONVENTIONAL RESERVOIRS

(71) Applicant: SAUDI ARABIAN OIL COMPANY, Dhahran (SA)

(72) Inventors: Uchenna Odi, Missouri City, TX (US); Karri Reddy, Dhahran (SA); Cenk Temizel, Dhahran (SA); Andrew Silver, Houston, TX (US); Tandy Lofland, Houston, TX (US); Nathan Meehan, College Station, TX (US)

(73) Assignees: ARAMCO SERVICES COMPANY, Houston, TX (US); SAUDI ARABIAN OIL COMPANY, Dhahran (SA)

(21) Appl. No.: 18/891,673

(22) Filed: Sep. 20, 2024

Related U.S. Application Data
(60) Provisional application No. 63/539,924, filed on Sep. 22, 2023.

(51) Int. Cl. G06F 30/27; E21B 47/06

(52) U.S. Cl. CPC G06F 30/27; E21B 47/06; E21B 2200/20; E21B 2200/22

(57) ABSTRACT

A method to determine locations of new wells that includes receiving grid data for a region containing a hydrocarbon reservoir and discretizing the region into a plurality of blocks. The method further includes receiving optimization parameters that include at least one production objective, where the production objective specifies a desired hydrocarbon production from the hydrocarbon reservoir over a period of time and determining a deliverability magnitude for each block in the plurality of blocks based on the grid data, where the deliverability magnitude is based on a permeability and a net pay for each block. The method further includes proposing one or more proposed well locations based on the deliverability magnitude, forecasting the production through time of the one or more proposed well locations, and selecting and scheduling one or more proposed well locations to meet the at least one production objective based on the forecasted production.

### BACKGROUND

The extraction and production of oil and gas from a well, or an oil and gas field composed of at least one well, is a complex process. The production properties of a reservoir, accessed by one or more well, will change over time. For example, reservoir production may change due to falling pressure and increased water content. Over the lifecycle of the oil and gas field many decisions will be taken in order to meet both short- and long-term production goals and extend the life cycle of a well.

In many scenarios, oil and gas field operators may desire to achieve and maintain a specified production level. However, due to a variety of factors, such as variable pressure-volume-temperature (PVT) behavior of reservoir, production may decline. Production decline may be more prominent, and less predictable, in unconventional gas basins with ultra-low permeability reservoirs. Whatever the situation, to maintain production targets additional wells may need to be drilled. Well planning (e.g., placement), drilling, and scheduling activities are typically associated with capital and facility constraints that further complicate these activities. As such, there exists a need to for a transformation workflow to optimize the placement and scheduling of new wells to meet and maintain production objectives of a reservoir while considering physical, economical, and business constraints.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

Embodiments disclosed herein generally relate to a method to determine locations of new wells that includes receiving grid data for a region containing a hydrocarbon reservoir and discretizing the region into a plurality of blocks. The method further includes receiving optimization parameters that include at least one production objective, where the production objective specifies a desired hydrocarbon production from the hydrocarbon reservoir over a period of time and determining a deliverability magnitude for each block in the plurality of blocks based on the grid data, where the deliverability magnitude is based on a permeability and a net pay for each block. The method further includes proposing one or more proposed well locations based on the deliverability magnitude, forecasting the production through time of the one or more proposed well locations, and selecting and scheduling one or more proposed well locations to meet the at least one production objective based on the forecasted production.

Embodiments disclosed herein generally relate to an intelligent field development system that includes an oil and gas field with an associated hydrocarbon reservoir and one or more computer processors. The one or more computer processors are configured to receive grid data for the oil and gas field and discretize the region into a plurality of blocks. The one or more computer processors are further configured to receive optimization parameters that include at least one production objective, where the production objective specifies a desired hydrocarbon production from the hydrocarbon reservoir over a period of time and determine a deliverability magnitude for each block in the plurality of blocks based on the grid data, where the deliverability magnitude is based on a permeability and a net pay for each block. The one or more computer processors are further configured to propose one or more proposed well locations based on the deliverability magnitude, forecast the production through time of the one or more proposed well locations, and select and schedule one or more proposed well locations to meet the at least one production objective based on the forecasted production.

Embodiments disclosed herein generally relate to a non-transitory computer readable medium storing instructions executable by a computer processor, where the instructions include functionality for receiving grid data for a region containing a hydrocarbon reservoir and discretizing the region into a plurality of blocks. The instructions further include functionality for receiving optimization parameters that include at least one production objective, where the production objective specifies a desired hydrocarbon production from the hydrocarbon reservoir over a period of time and determining a deliverability magnitude for each block in the plurality of blocks based on the grid data, where the deliverability magnitude is based on a permeability and a net pay for each block. The instructions further include functionality for proposing one or more proposed well locations based on the deliverability magnitude, forecasting the production through time of the one or more proposed well locations, and selecting and scheduling one or more proposed well locations to meet the at least one production objective based on the forecasted production.

Other aspects and advantages of the claimed subject matter will be apparent from the following description and the appended claims.

### BRIEF DESCRIPTION OF DRAWINGS

FIG. 1 depicts a wellsite in accordance with one or more embodiments.

FIG. 2 depicts the components and connectivity of the components of an intelligent field development system, in accordance with one or more embodiments.

FIG. 3 depicts an example graphical user interface of an intelligent field development system in accordance with one or more embodiments.

FIG. 4 depicts example feature importance rankings developed from machine-learned models configured to predict production rates, in accordance with one or more embodiments.

FIG. 5A depicts an example matched type curve for annual gas rates and calculated monthly rates.

FIG. 5B depicts an example matched type curve for condensate rates and calculated monthly rates.

FIG. 5C depicts an example matched type curve for annual condensate rates and calculated monthly matched rates.

FIG. 5D depicts an example matched type curve for cumulative condensate and matched cumulative condensate.

FIG. 5E depicts an example matched type curve for actual and matched condensate yield in B/MM vs cumulative condensate.

FIG. 6 depicts PVT behavior of an oil and gas field in accordance with one or more embodiments.

FIG. 7 depicts well pads and underground well configuration of an unconventional oil and gas field in accordance with one or more embodiments.

FIG. 8 depicts features of a single lateral of an unconventional well in accordance with one or more embodiments.

FIG. 9 depicts the area of a well pad composed of four wells in accordance with one or more embodiments.

FIG. 10 depicts the footprint of a well pad composed of multiple four well pads in accordance with one or more embodiments.

FIG. 11 depicts an overview of an intelligent field development system in accordance with one or more embodiments.

FIG. 12 depicts a high-level overview of the inputs and output of an intelligent field development system in accordance with one or more embodiments.

FIG. 13 depicts an example deliverability magnitude map in accordance with one or more embodiments.

FIG. 14 depicts an example well placement map in accordance with one or more embodiments.

FIG. 15 depicts a flowchart in accordance with one or more embodiments.

FIG. 16 depicts a neural network in accordance with one or more embodiments.

FIG. 17 depicts a flowchart in accordance with one or more embodiments.

FIG. 18 depicts a computing system, in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before,” “after,” “single,” and other such terminology. Rather, the use of ordinal numbers is to distinguish between the elements. By way of an example, a first element is distinct from a second element, and the first element may encompass more than one element and succeed (or precede) the second element in an ordering of elements.

It is to be understood that the singular forms “a,” “an,” and “the” include plural referents unless the context clearly dictates otherwise. Thus, for example, reference to “optimization constraint” includes reference to one or more of such constraints.

Terms such as “approximately,” “substantially,” etc., mean that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

It is to be understood that one or more of the steps shown in the flowchart may be omitted, repeated, and/or performed in a different order than the order shown. Accordingly, the scope disclosed herein should not be considered limited to the specific arrangement of steps shown in the flowchart.

Although multiple dependent claims are not introduced, it would be apparent to one of ordinary skill that the subject matter of the dependent claims of one or more embodiments may be combined with other dependent claims.

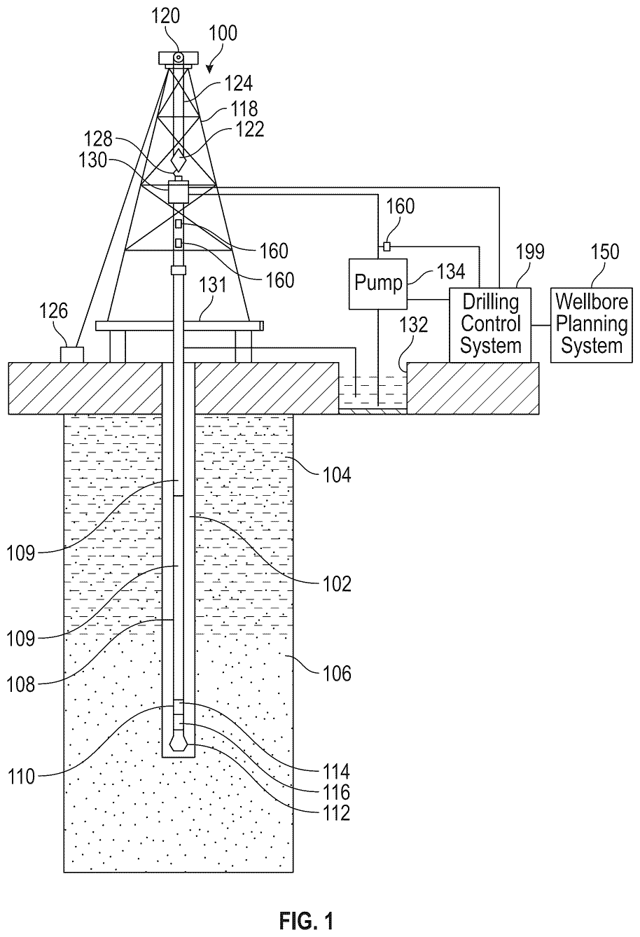

In the following description of FIGS. 1-18, any component described with regard to a figure, in various embodiments disclosed herein, may be equivalent to one or more like-named components described with regard to any other figure. For brevity, descriptions of these components will not be repeated with regard to each figure. Thus, each and every embodiment of the components of each figure is incorporated by reference and assumed to be optionally present within every other figure having one or more like-named components. Additionally, in accordance with various embodiments disclosed herein, any description of the components of a figure is to be interpreted as an optional embodiment which may be implemented in addition to, in conjunction with, or in place of the embodiments described with regard to a corresponding like-named component in any other figure.

FIG. 1 depicts a simplified well site (100). In general, well sites may be configured in a myriad of ways. Therefore, the illustrated well site (100) of FIG. 1 is not intended to be limiting with respect to the particular configuration of the drilling equipment. The well site (100) is depicted as being on land. In other examples, the well site (100) may be offshore, and drilling may be carried out with or without use of a marine riser. A drilling operation at well site (100) may include drilling a wellbore (102) into a subsurface including various formations (104, 106). The wellbore (102) may include a bored hole that extends from the surface into a target zone of the subsurface formations (104, 106), such as a reservoir. The subsurface formations (104, 106) may be categorized by various formation properties of interest, such as formation porosity, formation permeability, resistivity, density, water saturation, total organic content and the like. Properties of the subsurface formations (104, 106) may vary spatially.

For the purpose of drilling a new section of wellbore (102), a drill string (108) is suspended within the wellbore (102). The drill string (108) may include one or more drill pipes (109) connected to form conduit and a bottom hole assembly (BHA) (110) disposed at the distal end of the conduit. The BHA (110) may include a drill bit (112) to cut into the subsurface rock. The BHA (110) may include measurement tools, such as a measurement-while-drilling (MWD) tool (114) and logging-while-drilling (LWD) tool (116). Measurement tools (114, 116) may include sensors and hardware to measure downhole drilling parameters, and these measurements may be transmitted to the surface using any suitable telemetry system known in the art. By means of example, a LWD tool (116) commonly collects information about the properties of the subsurface formations (104, 106). As previously described, these may include, but are not limited to, the density, the porosity, and the resistivity of the subsurface formations (104, 106). The BHA (110) and the drill string (108) may include other drilling tools known in the art but not specifically shown.

The drill string (108) may be suspended in a wellbore (102) by a derrick (118). A crown block (120) may be mounted at the top of the derrick (118), and a traveling block (122) may hang down from the crown block (120) by means of a cable or drilling line (124). One end of the cable (124) may be connected to a draw works (126), which is a reeling device that may be used to adjust the length of the cable (124) so that the traveling block (122) may move up or down the derrick (118). The traveling block (122) may include a hook (128) on which a top drive (130) is supported.

The top drive (130) is coupled to the top of the drill string (108) and is operable to rotate the drill string (108). Alternatively, the drill string (108) may be rotated by means of a rotary table (not shown) on the drilling floor (131). Drilling fluid (commonly called mud) may be stored in a mud pit (132), and at least one pump (134) may pump the mud from the mud pit (132) into the drill string (108). The mud may flow into the drill string (108) through appropriate flow paths in the top drive (130) (or a rotary swivel if a rotary table is used instead of a top drive to rotate the drill string (108)).

In one implementation, a drilling control system (199) may be disposed at or communicate with the well site (100). Drilling control system (199) may control at least a portion of a drilling operation at the well site (100) by providing controls to various components of the drilling operation. In one or more embodiments, the drilling control system (199) may receive data from one or more sensors (160) arranged to measure controllable parameters of the drilling operation. As a nonlimiting example, sensors (160) may be arranged to measure WOB (weight on bit), RPM (drill string rotational speed), GPM (flow rate of the mud pumps), and ROP (rate of penetration of the drilling operation).

Sensors (160) may be positioned to measure parameter(s) related to the rotation of the drill string (108), parameter(s) related to travel of the traveling block (122), which may be used to determine ROP of the drilling operation, and parameter(s) related to flow rate of the pump (134). For illustration purposes, sensors (160) are shown on drill string (108) and proximate mud pump (134). The illustrated locations of sensors (160) are not intended to be limiting, and sensors (160) could be disposed wherever drilling parameters need to be measured. Moreover, there may be many more sensors (160) than shown in FIG. 1 to measure various other parameters of the drilling operation. Each sensor (160) may be configured to measure a desired quantity.

During a drilling operation at the well site (100), the drill string (108) is rotated relative to the wellbore (102), and weight is applied to the drill bit (112) to enable the drill bit (112) to break rock as the drill string (108) is rotated. In some cases, the drill bit (112) may be rotated independently with a drilling motor (not shown). In other embodiments, the drill bit (112) may be rotated using a combination of the drilling motor and the top drive (130) (or a rotary swivel if a rotary table is used instead of a top drive to rotate the drill string (108)). While cutting rock with the drill bit (112), mud is pumped into the drill string (108).

The mud flows down the drill string (108) and exits into the bottom of the wellbore (102) through nozzles in the drill bit (112). The mud in the wellbore (102) then flows back up to the surface in an annular space between the drill string (108) and the wellbore (102) with entrained cuttings. The mud with the cuttings is returned to the mud pit (132) to be circulated back again into the drill string (108). Typically, the cuttings are removed from the mud, and the mud is reconditioned as necessary, before pumping the mud again into the drill string (108). In one or more embodiments, the drilling operation may be controlled by the drilling control system (199).

As noted, the well site (100) provides well logs either through measurement tools (114, 116) while drilling or by post-drilling surveys such as a wireline tool (not shown). Furthermore, data about the subsurface formations (104, 106) near a well site (100) may be obtained by analyzing the entrained cuttings, as a function to drilling depth, exiting the wellbore (102). In addition to data acquired at a well-site, other methods for collecting data and characterizing subsurface formations (104, 106) exist. For example, a seismic survey may be conducted.

Prior to the commencement of drilling, a wellbore plan may be generated. The wellbore plan may include a starting surface location of the wellbore (102), or a subsurface location within an existing wellbore (102), from which the wellbore (102) may be drilled. Further, the wellbore plan may include a terminal location that may intersect with a target zone (e.g., a hydrocarbon-bearing formation) and a planned wellbore path from the starting location to the terminal location. In other words, the wellbore path may intersect a previously located hydrocarbon reservoir.

Typically, the wellbore plan is generated based on best available information at the time of planning from a geophysical model, geomechanical models encapsulating subterranean stress conditions, the trajectory of any existing wellbores (which it may be desirable to avoid), and the existence of other drilling hazards, such as shallow gas pockets, over-pressure zones, and active fault planes

The wellbore plan may include wellbore geometry information such as wellbore diameter and inclination angle. If casing is used, the wellbore plan may include casing type or casing depths. Furthermore, the wellbore plan may consider other engineering constraints such as the maximum wellbore curvature (“dog-log”) that the drill string (108) may tolerate and the maximum torque and drag values that the drilling system may tolerate.

A wellbore planning system (150) may be used to generate the wellbore plan. The wellbore planning system (150) may comprise one or more computer processors in communication with computer memory containing the geophysical and geomechanical models, information relating to drilling hazards, and the constraints imposed by the limitations of the drill string (108) and the drilling system. The wellbore planning system (150) may further include dedicated software to determine the planned wellbore path and associated drilling parameters, such as the planned wellbore diameter, the location of planned changes of the wellbore diameter, the planned depths at which casing will be inserted to support the wellbore (102) and to prevent formation fluids entering the wellbore, and the drilling mud weights (densities) and types that may be used during drilling the wellbore.

In one aspect, embodiments disclosed herein relate to an intelligent field development system capable of receiving data related to subsurface formations including one or more reservoirs, as well as user-specified objectives and constraints, and determine the optimal placement of one or more wells. In one or more embodiments, the intelligent field development system determines both the optimal location of a well site and a date by which the well site should be operational. The intelligent field development system can consider facility and economical constraints, among other factors, when proposing the locations of well sites. In one or more embodiments, the intelligent field development system further estimates the production of one or more proposed wells throughout their lifetime, while taking into account interaction with other wells and the state of the reservoir. The intelligent field development system can further calculate the uncertainty surrounding production estimates and determine subsurface features and operational parameters with the greatest affect on production. In one or more embodiments, the intelligent field development system relates various production quantities will well site features and subsurface properties using a suite of machine-learned models.

Typically, oil and gas field planning is associated with difficulties relating to modeling production and scheduling development. For example, an operator may wish to maintain a desired hydrocarbon output over a period of time. In other instances, an operator may wish to schedule a production period, for example as a function, over a period. In many scenarios, hydrocarbon production decreases with time requiring the drilling of new wells in order to meet the desired production profile of an operator. Complexities with production modeling and well site planning and scheduling are particularly prevalent in unconventional gas basins with ultra-low permeability reservoirs. For unconventional reservoirs, despite massive multi-stage hydraulic fracture stimulations, these reservoirs exhibit steep production declines and variable pressure-volume-temperature (PVT) behavior such that a given production rate cannot be maintained without adding new wells. In general, capital and facilities constraints further complicate well scheduling and planning. The intelligent field development system described herein mitigates difficulties with wellsite planning and scheduling activities by determining the location of wellsite with the greatest production opportunity (i.e., deliverability) and determining when a date indicating when a well should be operational in order to counteract the declining production of other wells in the field while considering all operational and economical constraints. Further, through feature importance and uncertainty analyses, the intelligent field development system may inform a user which features and/or subsurface properties have the greatest impact on production, deliverability, and well site placement. Use of the intelligent field development system removes human biases and error associated with determining well placement. Throughout the instant disclosure, examples of the intelligent well development system applied to an unconventional gas basin are demonstrated. While these examples may reference an unconventional gas basin, one with ordinary skill in the art will recognize that the intelligent field development system described herein is not limited to this type of reservoir and/or field. In general, the intelligent field development system may be applied to any oil and gas field to optimize and schedule the placement of wells.

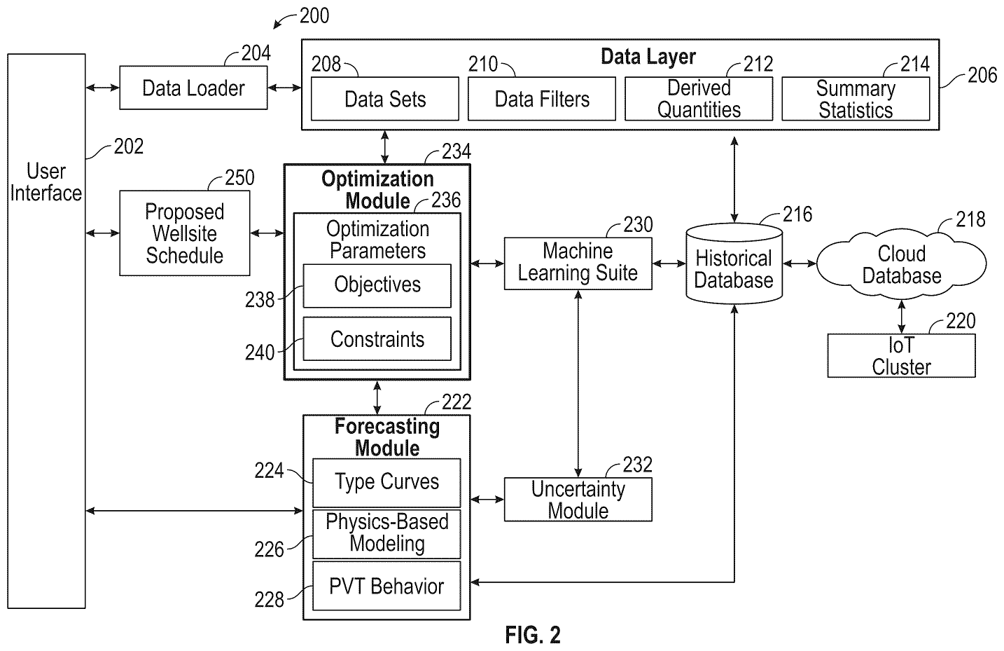

FIG. 2 depicts the intelligent field development system (200) in accordance with one or more embodiments. In FIG. 2, the intelligent field development system (200) is depicted as being comprised of various components and/or modules, where the components and/or modules may interact with each other. One with ordinary skill in the art will recognize that the partitioning, organization, and interaction of the components and/or modules of the intelligent field development system (200) in FIG. 2 is intended to promote clear discussion and should not be considered fixed or limiting. For example, FIG. 2 depicts a data loader (204) as an independent entity, however, it is well understood that in practice the data loader (204) may be implemented as part of the user interface (e.g., through a “front end” coding effort) or part of the data layer (206) (e.g., through a “back end” coding effort).

As depicted in FIG. 2, in one or more embodiments, the intelligent field development system (200) includes a user interface (202). In one or more embodiments, the user interface (202) is a graphical user interface. The user interface (202) acts as the point of human-computer interaction and communication. Thus, the user interface (202) can receive inputs from a user. Through the user interface (202), a user may upload data used by components and/or modules of the intelligent field development system (200). The user interface (202) further provides visualizations, such as graphs (e.g., geospatial maps), reports (e.g., summary statistics (214)), and text and image data, to one or more users. In broad terms, the user interface (202) can include display screens, keyboards, and a computer mouse. In one or more embodiments, the user interface (202) is implemented as a computer program, such as a native application or a web application.

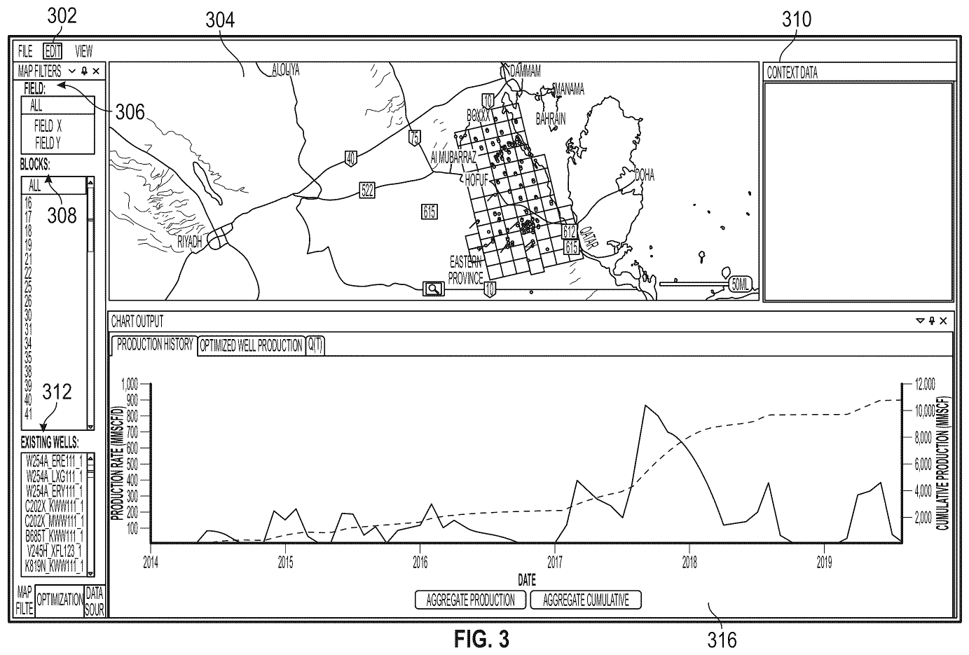

FIG. 3 depicts an example graphical user interface provided by the user interface (202), in accordance with one or more embodiments. As seen, in one or more embodiments, the example graphical user interface provides a menu (302) with one or more buttons that direct users to specific resources, content, and/or other menus. The user interface (202) provides a convenient and user-friendly mechanism to access functionality provided by the intelligent field development system (200). For example, in one or more embodiments, the intelligent field development system (200) allows for interaction with and visualization of maps (304) of a region associated with a hydrocarbon reservoir and graphs (316) plotting properties (e.g., production) of an oil and gas field or well. As seen in FIG. 3, in one or more embodiments, the user interface (202) of the intelligent field development system (200) provides access to data filters (210) to organize and visualize data according to specified fields (306), blocks (308), and existing wells (312), among other things. These concepts will be described in greater detail later in the instant disclosure. In one or more embodiments, maps (304) and graphs (316) displayed through the user interface (202) are automatically and dynamically updated and populated based on the selected data filters (210). Further, in one or more embodiments, the user interface (202) may provide a context menu (310) to aid a user in using the intelligent field development system (200) by providing information relevant to the user's current action.

Returning to FIG. 2, in one or more embodiments, the intelligent field development system (200) includes a data loader (204). In one or more embodiments, the data loader (204) can directly receive and parse oil and gas field data, such as subsurface property data, production and operational data from existing wells, and type curve data. The data loader (204) is configured to received data from multiple different data sources and of many different data types. In one or more embodiments, the data loader (204) can convert data types and merge data from disparate sources.

In one or more embodiments, the intelligent field development system (200) further includes a data layer (206). In general, the data layer (206) may include, but is not limited to: data sets (208), where each data set may represent a subsurface property over a region of interest (e.g., porosity, permeability); data filters (210) where a data filter may sort and omit data from one or more data sets (208) based on a specified feature of the data set; derived quantities (212) where a derived quantity may be a value determined through a functional or computed combination of one or more data sets (208) (e.g., deliverability); and summary statistics (214) where summary statistics provide aggregate representations of received and stored data.

Generally, a data set (208) contains a digital description of the physical properties of the subsurface as a function of position. Examples of subsurface properties that may be stored as a data set (208) include porosity and permeability. Additional data sets (208) may exist for properties such as density, resistivity, water saturation, and even depth. In some embodiments, the digital description may be in the form of a dense 3D grid with the physical properties of the subsurface defined at each node. In some embodiments, the 3D grid may be a cartesian grid, while in other embodiments the grid may be an irregular grid. In one or more embodiments, the intelligent field development system (200) stores subsurface property data, and well data, as “zmaps.” Zmaps are digitally compact compared to other grid file formats known in the art and, in the context of the instant disclosure, facilitate rapid spatial access to the subsurface properties at stratigraphic intervals of interest. Thus, in one or more embodiments, the intelligent field development system (200) stores grid data for a region of interest as zmaps. In one or more embodiments, the data loader (204) receives grid data and converts the grid data to an accepted zmap format, including regularization (e.g., adjust of grid node locations) if required. Grid regularization can be implemented using any technique known in the art, for example, linear interpolation. In summary, grid data describes the physical properties of the subsurface as a function of position, where the positions are generally given at discrete locations. In one or more embodiments, grid data may be organized into one or more data sets (208) where a single data set may correspond to a single property.

Grid data for the region of interest may be obtained from a variety of geological and geophysical sources. For example, remote sensing geophysical surveys, such as seismic surveys, gravity surveys, and active and passive source resistivity surveys, may be employed. In addition, data collected such as well logs (from measurement tools (114, 116)) and production data acquired in existing wells penetrating the reservoir may be used to determine physical and petrophysical properties along the segment of the well trajectory traversing the reservoir. For example, porosity, permeability, density, seismic velocity, and resistivity may be measured along these segments of wellbore. Data collected from previously drilled, nearby wells, sometimes called “offset” wells, may also be appended to the collected data. Moreover, so-called “soft” data, such as outcrop information and data describing analogous modern geological or depositional environments may be integrated with the acquired well site (100) data and seismic data to further refine the grid data (i.e., data sets ((208)). In accordance with some embodiments, remote sensing geophysical surveys and physical and petrophysical properties determined from well logs may be combined to estimate physical and petrophysical properties for a region of interest forming one or more data sets (208).

In one or more embodiments, the data layer (206) includes data filters (210). Generally, a data filter (210) is a pre-defined ruleset for organizing, displaying, and serving data. For example, a data filter (210) may specify that only the subsurface property of porosity (contained by a data set (208)) should be displayed or considered in subsequent calculations (e.g., optimization by the optimization model (234)). Other examples of data filters (210) may include the capability to remove, or only consider, data from data sets (208) over a specified period (e.g., a date filter). Data filters (208) may also be applied to select subsets of wells, oil and gas fields, and/or discrete geographic regions (i.e., blocks) for evaluation, display, and comparison.

In one or more embodiments, the data layer (206) further includes derived quantities (212). The derived quantities include values and/or subsurface property distributions developed from the information contained in the data sets (208). In most cases, derived quantities (212) are calculated according to a set of rules and/or mathematical functions (i.e., “hard coding”). That is, in one or more embodiments, the data layer (206) includes a set of instructions for transforming and/or combining one or more data sets (208). An example of a derived quantity (212) may include determining the deliverability of discrete regions over a region of interest, where deliverability is the product of permeability and net pay.

In one or more embodiments, summary statistics (214) are produced by the intelligent field development system (214). In one or more embodiments, summary statistics (214) are automatically generated from the data sets (208). The summary statistics (214) may include calculation of minimum, maximum, mean, median, standard deviation, distinct count, and total count for each subsurface property and/or well attribute available.

In one or more embodiments, the intelligent field development system (200) stores time series data related to one or more wells in a historical database (216). Time series data may include production values and operational parameters with an associated timestamp. Data stored in the historical database (216) may be received through the data loader (204). In accordance with one or more embodiments, the intelligent field development system (200) further includes an internet of things (IoT) cluster (220). The IoT cluster (220) is a collective network of connected devices. The IoT cluster (220) provides a technology architecture that facilitates communication between its collective devices, the historical database (216) and, in some embodiments, a cloud database (218). The devices may include embedded sensors and/or edge devices disposed throughout an oil and gas field. For example, wells of an oil and gas field may be monitored using field devices such as multiphase flow rate meters (MPFMs), choke valves, and temperature and pressure sensors. In one or more embodiments, data collected from devices of the IoT cluster (220), or field devices in general, is actively recorded in the historical database (216). Communication between IoT cluster (220) devices may be facilitated through RFID, NFC, low-energy Bluetooth, low-energy wireless, low-energy radio protocols, LTE-A, and WiFi-Direct technologies. In one or more embodiments, the IoT cluster (220) can be used to determine oil and gas field production in real time and store such quantities in the historical database (216).

In accordance with one or more embodiments, the intelligent field development system (200) includes, or at least can interact with, a cloud database (218). In one or more embodiments, the cloud database (218) provides interconnectivity for the IoT cluster (220) and other components/modules of the intelligent field development system (200).

In accordance with one or more embodiments, the intelligent field development system (200) includes a machine-learning suite (230). Machine learning, broadly defined, is the extraction of patterns and insights from data. The phrases “artificial intelligence”, “machine learning”, “deep learning”, and “pattern recognition” are often convoluted, interchanged, and used synonymously throughout the literature. This ambiguity arises because the field of “extracting patterns and insights from data” was developed simultaneously and disjointedly among a number of classical arts like mathematics, statistics, and computer science. For consistency, the term machine learning, or machine-learned, will be adopted herein, however, one skilled in the art will recognize that the concepts and methods detailed hereafter are not limited by this choice of nomenclature. The machine-learning suite (230) provides functionality to train and use one or more machine-learned models. The concept of training machine-learned models will be described in greater detail later in the instant disclosure. However, for now, it may be said that in one or more embodiments the machine-learning suite (230) trains one or more machine-learned models to predict well production values given well and reservoir attributes. For example, a machine-learned model may be trained to predict the quantity of produced condensates from a well given properties of the reservoir such as porosity, total organic content, and initial reservoir pressure and well attributes such as the state of a choke valve.

In one or more embodiments, the machine-learning suite (230) produces machine-learned models to predict gas production, condensate production, water production, and condensate gas ratio (CGR). The machine-learned models may operate on the level of individual wells, on subsets of wells, and on oil and gas fields. In one or more embodiments, the machine-learned models are further evaluated to determine the relative importance of the input features in predicting the target quantity (i.e., water production, gas production, condensate production, and condensate gas ratio (CGR)). Determination of the relative importance of input features is hereafter referred to as feature importance ranking. In one or more embodiments, machine-learned model features are ranked according to a change in model prediction accuracy when a feature is removed or randomly perturbed (“X scrambling”). In one or more embodiments, prediction accuracy is measured using an r-squared metric, where the r-squared metric compares the variance of residuals of a proposed and trained model to the observed variance of the target quantity.

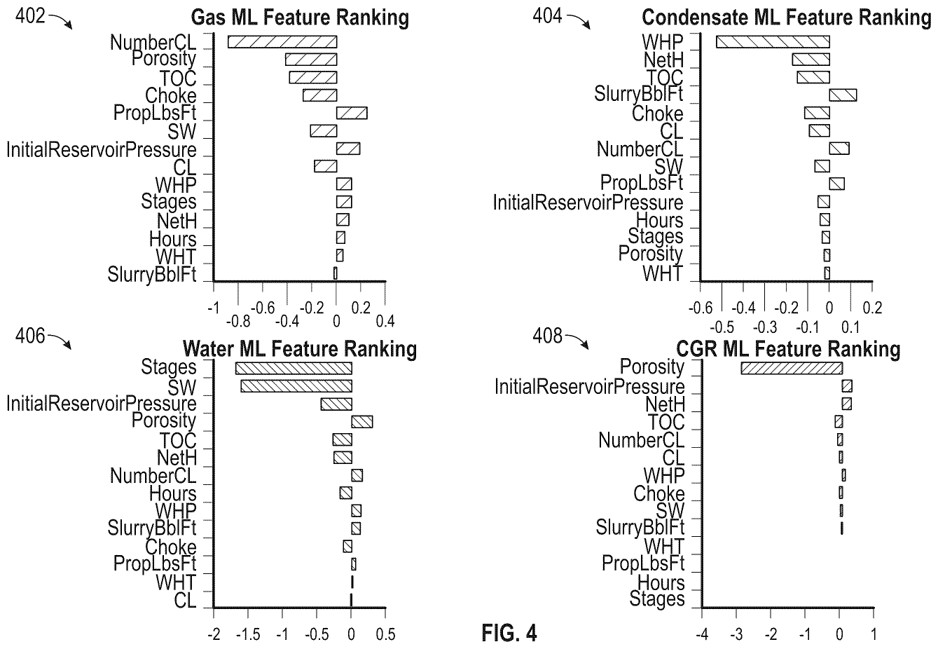

As an example of the feature importance ranking, as produced by the intelligent field development system (200), FIG. 4 depicts the feature importances for a given well for the targets of gas production, condensate production, water production, and condensate gas ratio (CGR). As seen in FIG. 4, features considered by the machine learning suite (230) in predicting the targets may include, but are not limited to: a number of stages; water saturation; initial reservoir pressure; porosity; total organic content (TOC); net pay; number of chlorides; well head pressure; slurry per foot; choke setting; proppant per foot; and well head temperature. Specifically, FIG. 4 depicts a gas feature ranking plot (402), a condensate feature ranking plot (404), a water feature ranking plot (406), and a gas condensate ratio feature ranking plot (408). As seen, in one or more embodiments, features are not only ranked according to their impact on the accuracy of the machine-learned model, but the positive or negative effect of a feature on the values of the target can also be quantified.

Keeping with FIG. 2, in one or more embodiments, the intelligent field development system (200) further includes a forecasting module (222). At a high level, the forecasting module (222) allows a user of the intelligent field development system (200) to predict, at least, the production of one or more wells. In one or more embodiments, the forecasting module (222) makes use of type curves (224), physics-based modeling (226), and pressure-volume-temperature (PVT) behavior consideration to forecast well production. In one or more embodiments, production data is loaded into the forecasting module (222). In some embodiments, the forecasting module (222) may directly access data, such as well production data, from the historical database (216).

At a high-level, the forecasting module (222) produces production forecasts by identifying and categorizing segments of the production data that correspond to different periods of production that are typically observed over the lifetime of a well. Further, identified segments are described by a set of parameters. In some embodiments, identified segments are matched to sets of pre-determined or pre-populated parameters. In other embodiments, a parameter set is elected based on the categorization of the segment and the parameters of the set are fit (i.e., tuned or adjusted) to align with the observed production data. In one or more embodiments, segmentation of the received production data is performed using an automated decline curve analysis (DCA) process and/or rate transient analysis (RTA) process. In general, DCA and RTA techniques analyze production data using a variety of rolling numerical analysis methods designed to programmatically highlight significant variations in production and pinpoint where different segments occurred. Once the segments have been determined, the data for each segment is passed to an algorithmic solver to determine the values for a parameter set that result in the best fit. In one or more embodiments, the employed solver uses the genetic algorithm to determine the parameter values.

The forecasting module (222) may use a combination of physics-based modeling (226), type curve analysis (234), and PVT behavior estimation (228) to forecast the production of one or more wells. In general, physics-based modeling (226) uses a set of flow equations to model, and thus forecast, production. The complexity of the set of flow equations used by a physics-based model depends on the accuracy required and whether any simplifying assumptions can be applied based on the properties of the reservoir and production flow without unreasonably decreasing the model accuracy. For example, in some situations the set of flow equations may be simplified such that conservation of mass is not enforced. without material balance considerations. In one or more embodiments, the forecasting module (222) includes many physics-based models and a user may select a desired modeling approach. In other embodiments, the forecasting module (222) interactions with, or otherwise makes use of, external physics-based models and software. For example, in one or more embodiments, the forecasting module (222) may initiate and run a reservoir simulator. In other embodiments, the forecasting module (222) receives production data, or even forecasts, from externally connected and commercially available software.

Typically, the physics-based modeling (226) requires inputs to form, close, and provide initial and boundary conditions to the set of flow equations. Common inputs may include initial pressure and temperature, hydrocarbons in place (e.g., area, porosity, saturations, thickness, etc.), subsurface formation properties (e.g., relative permeability for multiphase flow), PVT behavior (228), a detailed description of fracture properties (in the case of unconventional wells), and well operating conditions. In one or more embodiments, the forecasting module (222) provides default values for all required inputs for physics-based modeling (226) and allows a user to alter values where appropriate.

In one or more embodiments, the forecasting module (222) uses DCA methods, including rate transient analysis (RTA) to match observed production data of a well to a shape (i.e., curve or trend) derived theoretical considerations or historical observations. Often the shape (rate behavior) is the solution to a constant pressure drawdown of reasonably simple reservoir models. Modifications can be made to approximate more rigorous superposition calculations needed when certain boundary conditions are not met.

In one or more embodiments, the forecasting module (222) can realize DCA/RTA of production data through user-specified fits (i.e., human “eyeballing” of the data), curve fitting approaches, and machine learning. Regardless of approach used, typically, corrections are needed for a wide variety of non-theoretical behavior including early time cleanup, beanup, choke flow, choke changes, shut-ins and restimulations. In one or more embodiments, the forecasting module (222) allows for a user to make corrections, as required, and as more production data is made available (e.g., recorded in the historical database (216)).

In accordance with one or more embodiments, the forecasting module (222) may further use type curves (222) to consider rate and pressure transient behavior. Generally, a conventional type curve is a graphical representation of the theoretical response during a test or production performance of an interpretation model that represents the well and the reservoir being tested. Typically, type curves (224) are based on theoretical flow and/or material balance equations. In some instances type curves (224) are fitted to observed production data. One with ordinary skill in the art will recognized that there are many ways to generate type curves (224). Common approaches may include, but are not limited to: statistical methods based solely on producing data; empirical DCA/RTA using analytical or semi-analytical methods; numerical simulation methods; and statistical methods

In one or more embodiments the forecasting module (222) provides the capability to forecast production from type curves with user specified parameters. As an example, consider a user specified type curve for a PVT region of high CGR as given in TABLE 1.

TABLE I
Example of a gas condensate type curve specification

| YEAR | AVG MM/D | AVG B/D | CALC B/MM |
|---|---|---|---|
| 1 | 2.313 | 338 | 146.2602681 |
| 2 | 2.313 | 141 | 60.99434959 |
| 3 | 1.623 | 76 | 46.88847813 |
| 4 | 1.1975 | 46 | 38.79749478 |
| 5 | 0.933 | 34 | 36.35584137 |
| 6 | 0.7605 | 26 | 34.10913872 |
| 7 | 0.6225 | 21 | 34.3458153 |
| 8 | 0.5305 | 18 | 33.85485391 |
| 9 | 0.4845 | 16 | 32.36326109 |
| 10 | 0.4285 | 15 | 33.1584987 |
| 11 | 0.3925 | 13 | 34.14012739 |
| 12 | 0.358 | 11 | 31.06145251 |
| 13 | 0.3235 | 11 | 34.374034 |
| 14 | 0.289 | 10 | 34.53287197 |
| 15 | 0.266 | 9 | 33.23308271 |

For the current example and in accordance with one or more embodiments, the forecasting module (222) approximates the type curve using a period of constant production (zero to any number of years) followed by a hyperbolic decline which can optionally have a terminal decline rate. Additionally, for the example, condensate is modeled as a constant maximum value (typically the first-year or early time average) followed by a linear decline as a function of cumulative production to a minimum value. The equations supporting these models, and contained in the forecasting module (222), are as follows.

The flow rate of gas q (t) as a function of time, T, in years is given as

$$q ( t ) = \{ \begin{matrix}{q}_{init} & if T < {T}_{mos} \\ {{q}_{init} ( 1 + {bD}_{i} T )}^{- 1 / b} & otherwise\end{matrix} ,$$

where qᵢₙᵢₜ is the matched or specified initial gas flow rate, Tₘₒₛ is the number of months at constant rate (it is noted that for comparison of T (in years) to Tₘₒₛ the units are consistent), b is the hyperbolic decline exponent and may be greater than 1.0 for this implementation, and Dᵢ is the nominal decline rate.

Gas condensate production is typically constant above the dew point and generally declines to a minimum value over time. In one or more embodiments, the gas condensate decline is modeled as being linear with cumulative production. The equations for gas condensate is

$$BMM = min ( max ( {BMM}_{int} + slope * {g}_{cum} , {BMM}_{final} ) , {BMM}_{max} ) ,$$

where BMM is the calculated CGR in bbl per MMCF, g_{cum} is the cumulative gas on a per well basis in MMCF, and BMMᵢₙₜ is the y-axis intercept of the straight-line approximation for BMM. BMMᵢₙₜ is typically higher than any actual values that will be used and is a calculated value without obvious physical meaning. slope is the slope of the straight-line approximation for BMM, BMMₘₐₓ is either calculated or specified and refers to the maximum condensate yield observed in the field on a monthly basis, and BMM_{final} is likewise either calculated or specified and refers to the minimum condensate yield observed in the field on a monthly basis.

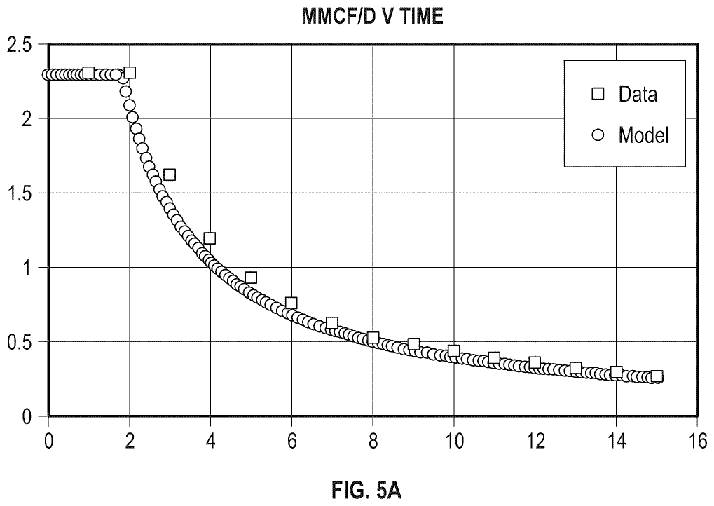

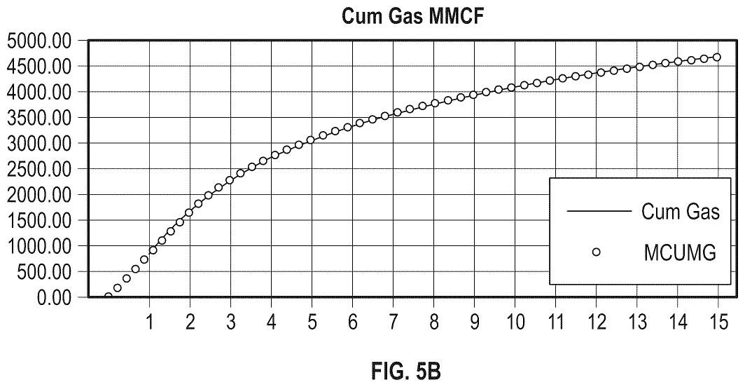

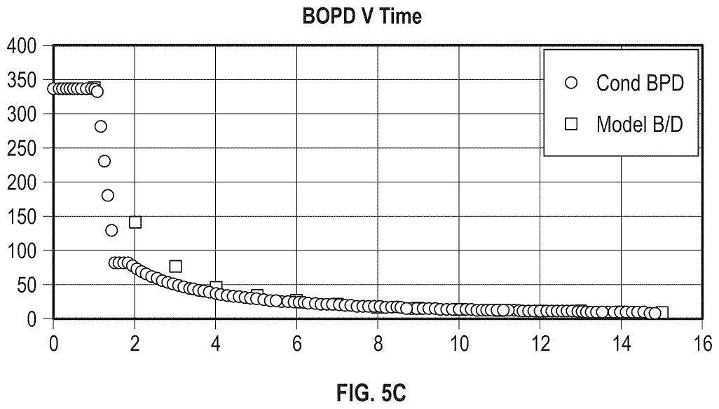

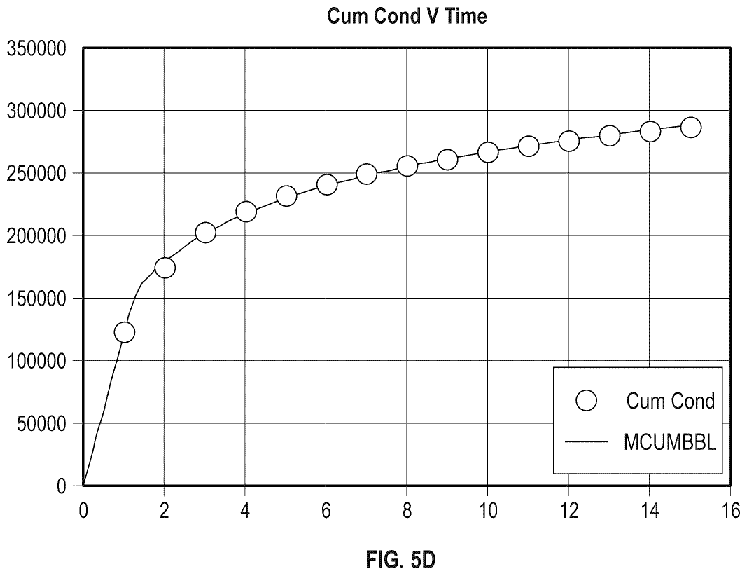

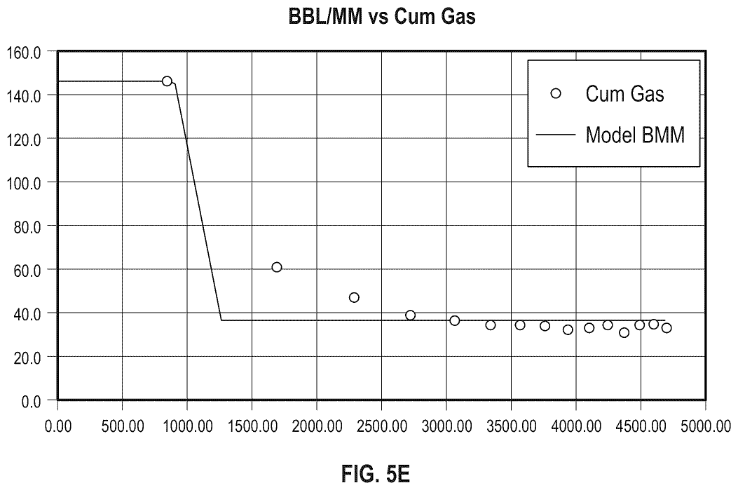

Continuing with the example, FIGS. 5A-5E depict the results of the type curve matching as performed by the forecasting module (222). Specifically, FIG. 5A depicts the annual type curve rates and calculated monthly matched rates for gas, FIG. 5B depicts the type curve cumulative gas with matched cumulative gas, FIG. 5C depicts the annual type curve rates and calculated monthly matched rates for condensate, FIG. 5D depicts the type curve cumulative condensate with matched cumulative condensate, and FIG. 5E depicts the actual and matched condensate yield in B/MM vs cumulative condensate.

In one or more embodiments the matching, or fitting, of the type curves is performed with a genetic algorithm. Generally, the genetic algorithm is beneficial because it is robust over a wider range of initial estimates. Further, in one or more embodiments, a user can modify the magnitude and shape of the type curve with by specifying the match parameters.

One with ordinary skill in the art will appreciate that the preceding example was provided for illustrative purposes only. In general, the forecasting module (222) may support any type curve and associated parameterized functions. As such, the preceding example should not be considered limiting on the instant disclosure. Further, in one or more embodiments, different type curves can be specified piecewise over a region of interest.

As previously mentioned, in one or more embodiments, the forecasting module (222) further considers the PVT behavior (228) of the region of interest. In general, PVT values are required whenever hydrocarbons in place must be calculated or forecast rate and recovery calculations are made with equations as opposed to type curve only approaches. For example, often values for the coefficient of isothermal compressibility of a natural gas, natural gas viscosity, and the gas formation volume factor are explicitly required. Both the coefficient of isothermal compressibility of a natural gas and the gas formation volume factor implicitly require the calculation of the nonideal gas deviation factor. One with ordinary skill in the art will recognize that complete description of PVT behavior for reservoir fluids exceeds the scope of this disclosure. However, it will be understood that the forecasting module (222), when considering PVT behavior (228), can determine, at least, the nonideal gas factor. In one or more embodiments, the forecasting module (222) accepts a user-supplied estimate of the nonideal gas factor, where the estimate may be determined from laboratory testing of reservoir fluids. In other embodiments, the nonideal gas factor is estimated using published correlations relating the nonideal gas factor to temperature and pressure. Likewise, in one or more embodiments, the forecasting module (222) contains known correlations to determine other quantities such as gas viscosity and gas compressibility.

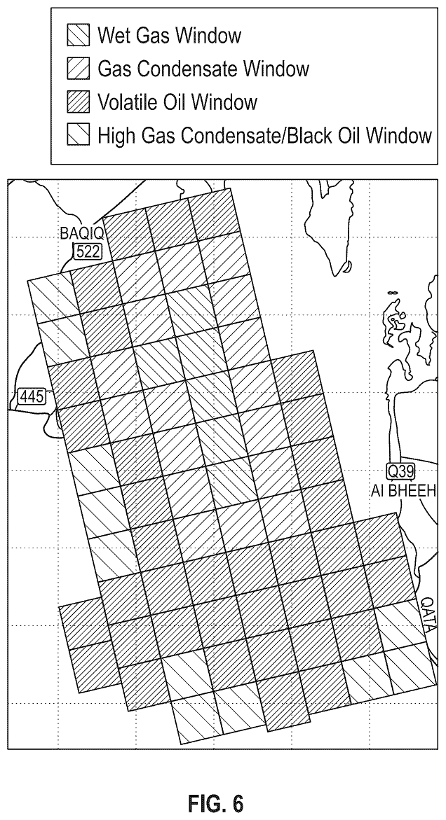

In one or more embodiments, PVT behavior (228), like the type curves (224) can be specified piecewise over a region of interest. For example, FIG. 6 depicts a region discretized into a plurality of blocks and the PVT behavior is specified or determined block-wise. In the example of FIG. 6, PVT behavior is categorized according to a wet gas window, a gas condensate window, a volatile oil window, and a high gas condensate/black oil window.

Finally, in one or more embodiments, the forecasting module (222) is further configured to account for “bean up” or other flow rate restrictions operators that may occur or apply early in the life of a well to potentially minimize proppant flow back, reflect the impacts of water cleanup, etc.

Continuing with FIG. 2, in one or more embodiments the intelligent field development system further includes an uncertainty module (232). The uncertainty module is capable of determining how sensitive production forecasts (from the forecasting module (222)) and machine-learned models (from the machine-learning suite (230)) are to various parameters. Parameters by which sensitivity is tested may include well operational parameters, fitted or specified type curve parameters, physics-based model parameters, and subsurface properties. In one or more embodiments, values of input parameters and/or model parameters are specified with a distribution. In one or more embodiments, the uncertainty module (232) propagates the uncertainty of one or more parameters through a machine-learned model and/or production forecast using a Monte Carlo simulation. Generally, a Monte Carlo simulation can be summarized as a statistical technique that has a relatively rigorous approach to inclusion of certain variables and yields a prediction of statistical outcomes. Monte Carlo simulations can account for partial dependencies and give realistic ranges of potential outcomes. For example, in one or more embodiments, the intelligent field development system (200) forecasts the mean (average or expected) value of wells required to reach a certain production target along with the so-called P₉₀ number of such wells. The latter value would be the number of wells required to ensure that there is only a 10% chance that drilling that number of wells would fail to meet production objectives.

In one or more embodiments, the intelligent field development system (200) includes an optimization module (234). In one or more embodiments, the optimization module (234) accepts, at least, the data sets (208) or grid data and outputs a proposed well schedule (250) according to a user-defined set of optimization parameters (236). The optimization parameters (236) may further be partitioned into one or more objectives (238) and one or more constraints (240). The proposed well schedule (250) specifies the number of wells, the location of said wells, and a date by when each well needs to be operational in order to meet a production objective over time. In one or more embodiments, the production objective may change with time and therefore may be specified as a function (e.g., piecewise function) of time.

In accordance with one or more embodiments, the optimization module (234) determines both the location and schedule for drilling wells by optimizing one or more objectives (238) subject to one or more constraints (240). Objectives may include, but are not limited to: specifying a gas rate over time (while minimizing well count); specifying gas rates and condensate rates over time; specifying gas rates over time while simultaneously maximize condensates; specifying gas rates over time while minimizing $/BOE (i.e., CAPEX+OPEX); specifying gas rates over time while maximizing approximated net present value (NPV); and specifying gas rates over time while maximizing both approximated NPV and condensates. In situations where more than one objective is stated, a Pareto front may be formed. In one or more embodiments, each objective may be weighted in order to determine an optimum point on the Pareto front, or at least reduce the number of optimal points on the Pareto front. The objectives (238) can be provided as functions over time. Further, the objective function(s) can be stated as the annual gas rates or gas rates as a function of time required, condensate rates, gas rates and condensate rates or gas rates while maximizing another function. In each case, the intelligent field development system (200) will schedule and forecast the number of wells (e.g., well pads) required to meet the objective function(s). Detailed descriptions of common objectives (238) are provided as follows. One with ordinary skill in the art will recognize that many types of objectives may be specified. In general, the intelligent field development system (200) allows a user to select a pre-specified objective (238), like those described below, or define a custom objective (238). As such, the intelligent field development system (200) is not limited to only the objectives (238) described herein.

The simplest objective commonly used by the optimization module (234) specifies that a single phase (e.g. gas) rate should be maximized, at least up to a specified target production, while minimizing the number of wells required. Under this objective (238), the optimization module (234) identifies as the next pad (or well) to drill as the pad with the highest potential contribution to flow rate (by default the first year's average contribution to flow rate). In one or more embodiments, it is possible to specify any other time period such as the first month flowrate or even ultimate recovery as the optimization criteria.

It is also possible to specify both gas rates and condensate rates as objectives (238). In general, the optimization module (234) will produce a proposed wellsite schedule (250) that results in one of the targets being hit exactly while the other one is overshot. It is noted that specifying two minimum values is only reasonable when it is possible to produce the other phase without restrictions. Under this objective (238), the optimization module (234) selects as the next pad (or well) to drill as that with the highest calculated flow rates of the phase that is limited.

In one or more embodiments, the optimization module (234) selects as the next well (or well pad) to drill as that with the highest contribution to condensate production while achieving forecast gas rates.

In one or more embodiments, the optimization module (234) proposes and schedules wells based on the largest revenue generation over their lifetime per BOE. For this objective (238), a user must specify a capital expense (CAPEX) proxy or other estimator. Typically, the initial rates are not used in this selection but the EUR, or occasionally gas recovery in a fixed time period (e.g. 10-year gas recovery), are used. Generally, OPEX costs (operating costs) are treated as fixed costs when expressed as $/well/month or $/pad/month. When OPEX costs are expressed as $/Mcf or $/bbl they are usually deducted from the user specified prices. As such prices must also be input and are usually not escalated for this undiscounted measure.

In one or more embodiments, the objective function specifies a forecast gas production rate while maximizing an approximated Net Present Value (NPV). This objective (238) requires considerably more economic parameter inputs such as discount rates and escalation rates for costs and prices.

In one or more embodiments, the optimization module (234) of the intelligent field development system (200) further considers one or more constraints (240). For example, consider the case where gas rate is optimized (i.e., maximizing a gas rate objective) without regard to the technical or economic feasibility of actually drilling the wells proposed in the proposed wellsite schedule (250). Specifically, consider a case where the objective specifies a desired production rate of 0.5 Bcf/D for 3 years followed by 5 years of 5.0 Bcf/D. Without constraints in place, this would generate a drilling schedule that requires (briefly) a huge increase in drilling rigs that would then be largely released. Such an activity might be both impossible and/or considered an unsound business practice. Thus, in one or more embodiments, the optimization module (234) performs any optimization subject to one or more constraints (240). For example, constraints (240) may include specifying the maximum number of wells (or well pads) that can be constructed over a period of time. Other common constraints may include specifying the physical footprint, or other geometric constraints, associated with a well and/or well pad. Further, optimization parameters (236) may take into account a desired configuration of a well pad. To demonstrate these features, the well geometry of an unconventional well is considered and provided as an example. However, one with ordinary skill in the art will understand that analogous geometric constraints may be supplied for any type of well. As such, the intelligent field development system (200) disclosed herein is not limited to unconventional wells.

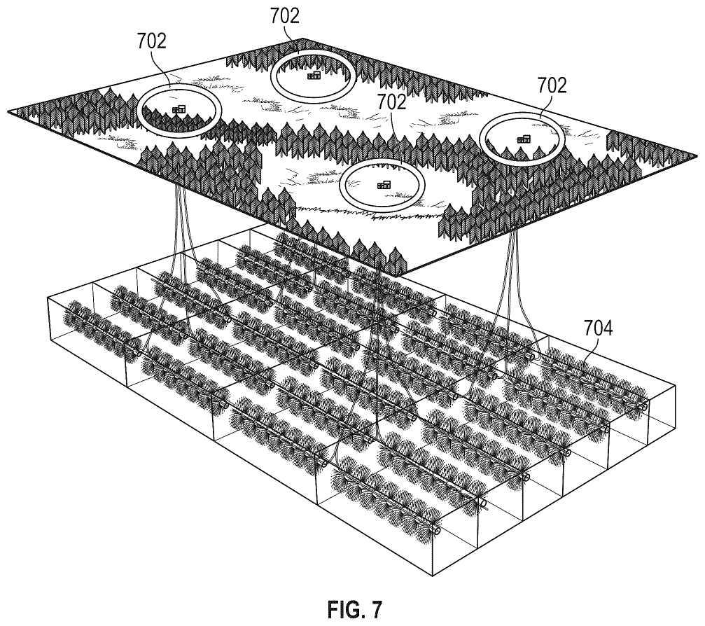

Nomenclature for unconventional well geometries varies throughout the literature. The nomenclature used herein is as follows. A group of individual wells is often drilled from a single location known as a pad. The wellheads of a pad are at closely spaced surface locations with the distances between wellheads based on rig and operational decisions. Typically, pad drilling reduces the time required to move from one well to another as the entire rig can be “skidded” to the next location. Further, pad drilling may lower operating costs, decrease the costs of production facilities and gathering lines, decrease the need for flaring, simplify certain artificial lift requirements, and lower fracture stimulation costs (for example by minimizing fluid and proppant storage needs and other environmental benefits). FIG. 7 depicts an unconventional gas field with four well pads (702). As seen in FIG. 7, each well pad (702) is composed of six wells (704). To promote ease of viewing the figure, a labelling line is not drawn to each well (704) in FIG. 7.

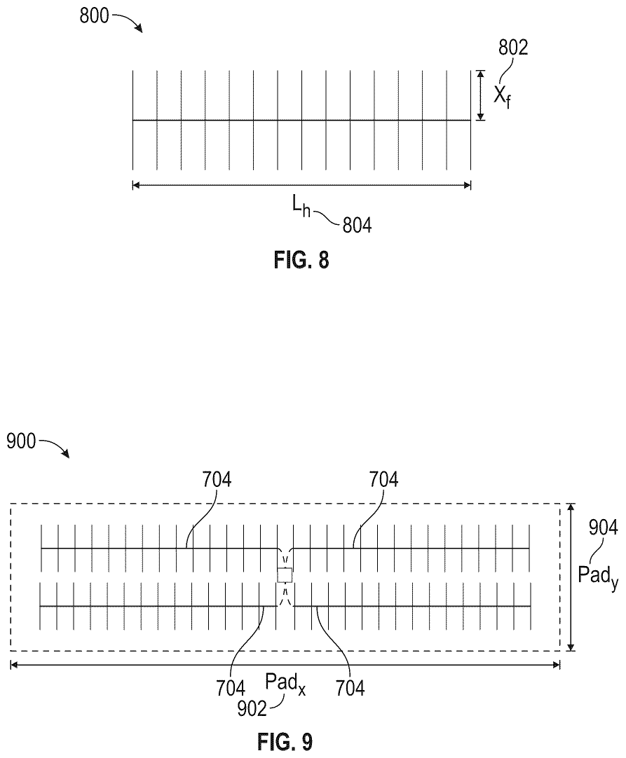

FIG. 8 depicts a representation of a single lateral (800) for an unconventional well. Herein, the fracture half-length (802) is represented by x, and the total lateral length (804) exposed to the formation is given by Lₕ. Typically, each stage consists of multiple perforations within a portion of the n fracture stages in a lateral. While these are represented as individual fractures, there will in fact be multiple perforation clusters within a stage. It is typical that the entire fracture stage is not perforated uniformly but is perforated with multiple small fracture clusters. Hydraulic fractures are likely to initiate at multiple, if not each of the perforation clusters. Thus, the stage length, lₛ, may vary but is approximately (for a large number of fracture stages)

$${l}_{s} = \frac{{L}_{h}}{n - 1} \sim \frac{{L}_{h}}{n} .$$

Pads of a dozen or more wells are common. The closest reasonable “tip-to-tip” (or “toe-to-toe” on adjacent pads) well spacing is lₛ. Generally, individual laterals should be spaced at least 2x_{ƒ} apart to minimize fracture interaction and allow for additional drainage. The well pad area for unconventional wells is demonstrated in FIG. 9. Specifically, FIG. 9 depicts the area of a well pad with four wells (704) (i.e., a “four well” pad (900)). The well pad area is given in terms of a longitudinal length (902), Padₓ, and a transverse length (904), Pad_{y}. Thus, the pad area is simply

$$area = {Pad}_{x} * {Pad}_{y} .$$

The longitudinal length (902) is defined as

$${Pad}_{x} = 2 ( {L}_{h} + {l}_{s} ) .$$

And the transverse length is given as

$${Pad}_{y} = 2 * IWS ,$$

where IWS is the interwell spacing.

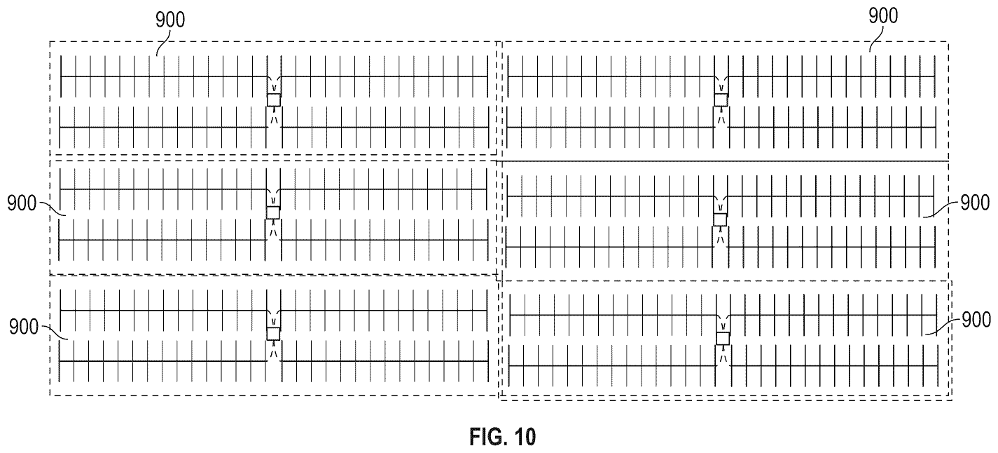

Well pad configuration is not limited to that shown in FIG. 9. For example, a well pad may be combined to form larger well pads. FIG. 10 depicts an example of a well pad composed of six of the “four well” pads (900) depicted in FIG. 9. In such a case, the well pad longitudinal length (902) and transverse length (904) is simply the additive sum of the individual pads.

In one or more embodiments, the geometric constraints, such as well spacing, lateral length, and wells per pad, are included as constraints (240) in the optimization module (234). Thus, when selecting and scheduling wells to meet one or more objectives (234), the intelligent field development system (200) considers whether a well can physically be placed in a proposed location.

As stated, a principal output of the intelligent field development system (200) is the proposed well schedule (250). The proposed well schedule (250) specifies the number of wells (or pads), the location of said wells, and a date by when each well needs to be operational in order to meet a production objective over time. In one or more embodiments the proposed well schedule (250) is determined by the optimization model (234) according to user-specified optimization parameters (234). As seen in FIG. 2, in one or more embodiments, the optimization module (234) is coupled with the forecasting module (222) and data layer (206) to directly receive grid data and production forecasts when generating the proposed wellsite schedule (250).

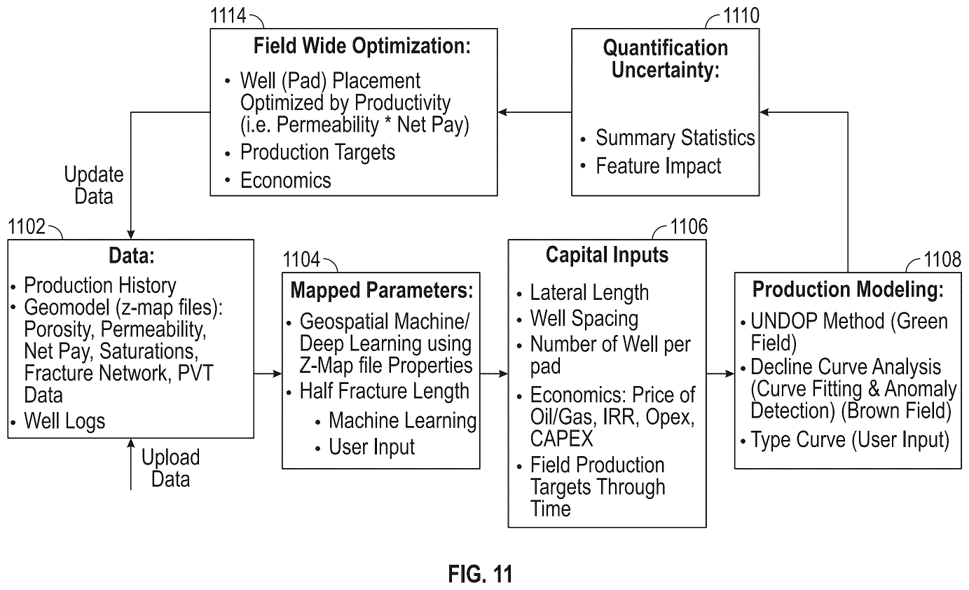

An alternative viewpoint of the intelligent field development system (200) and its processes is depicted in FIG. 11, in accordance with one or more embodiments. As seen in FIG. 11, the intelligent field development system (200) is instantiated through a data upload process. As depicted in Block 1102, the uploaded data may include the production history for one or more wells, along with well logs, and a geological model describing the subsurface. In one or more embodiments, the geological model includes grid data, that may be uploaded as one or more data sets, descriptions of the fracture network (in the case of unconventional wells), and PVT data. In Block 1104, the uploaded data is used to provide estimates of subsurface properties at locations where data is not directly available. Thus, in Block 1104, geospatial and geometric data is mapped over the region of interest. The mapping of parameters over a region of interest can be performed with any technique known in the art, including interpolation, machine-learning, and/or grid regularization techniques. In one or more embodiments, geospatial data is converted and stored in a zmap format. In Block 1106, optimization parameters are received. The optimization parameters include capital inputs such as the price of oil and gas, OPEX, and CAPEX. The optimization parameters further include well and field production targets (objects) and constraints such at well spacing, number of wells per pad, and number of wells that can reasonably be constructed in a given time period. In Block 1108, production forecasts for existing and proposed wells are constructed using DCA and type curves. In Block 1110, the uncertainty of production forecasts and model sensitivity to model inputs (e.g., machine-learned model feature importance ranking) is conducted. Further, in Block 1110, summary statistics for the geospatial data, production data, and other received data is generated and reported. In Block 1114, the optimal location (i.e., placement) of wells (and/or well pads) over an oil and gas field is determined along with a schedule in order to meet the specified production targets (objectives) subject to any provided constraints. As new wells are drilled and become operational, additional well logs, subsurface property data, and production data of the new wells is uploaded to the previously received data. By continually updating the data, the intelligent field development system (200) can update subsurface property maps and production forecasts to better determine the locations and scheduling of future wells.

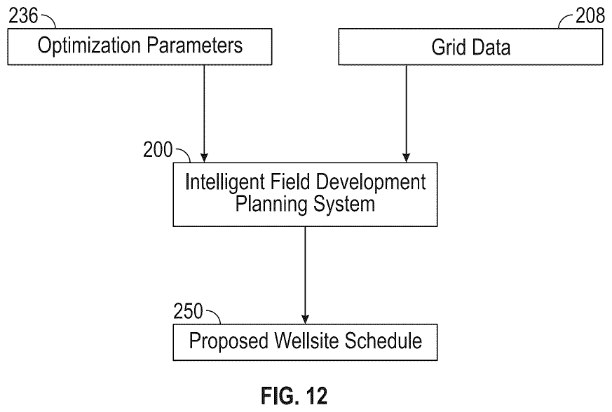

FIG. 12 depicts a high-level overview of the inputs and outputs associated with the intelligent field development system (200). In general, the intelligent field development system (200) receives, or forms, grid data (i.e., data sets (208)) for a region of interest along with optimization parameters (236) that specify, at least, an objective. In one or more embodiments, the objective relates to a production target over a period of time. In one or more embodiments, the optimization parameters (236) further include one or more constraints, where a constraint may be physically- or economically-motivated and/or specify a desired wellsite configuration. In accordance with one or more embodiments, the intelligent field development system (200) processes the grid data (208) in view of the optimization parameters (236) and outputs a proposed wellsite schedule (250). The proposed wellsite schedule indicates both a location for placement of a new well along with a date by which the new well should be operational in order to meet desired production targets.

In one or more embodiments, the intelligent field development system (200) determines the optimal location of new wells by first discretizing a region of interest (over which grid data is available) into a plurality of blocks and determining the deliverability of each block. Well location is prioritized to blocks with the highest deliverability until no more wells can be placed in a block or the production target is achieved. The production of existing and proposed wells is forecast through time to account for expected declines in production. Upon detecting that the forecasted production will not meet the desired production target, the intelligent field development system (200) schedules a well to become operational at the next available highest deliverability location.

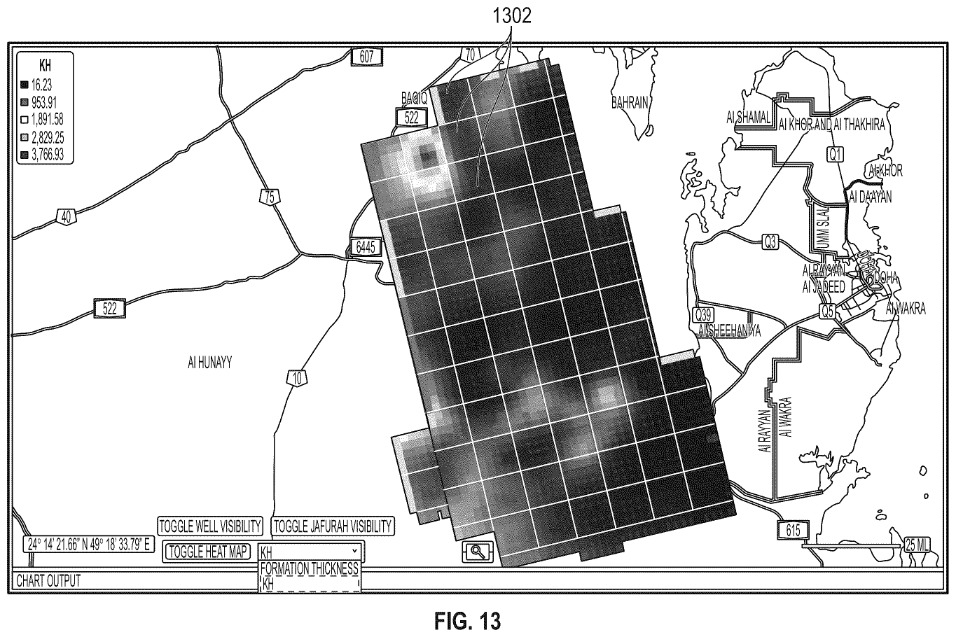

FIG. 13 depicts a region of interest that has been discretized into a plurality of blocks (1302). To avoid cluttering the figure, not all blocks have been annotated with a numeric label, however, the resolution of the discretization is readily observed through the shading of the blocks. In accordance with one or more embodiments, a value for permeability and net pay is determined from the grid data. The intelligent field development system (200) determines a value for deliverability for each block where deliverability is defined as

$$deliverability = permeability * net pay .$$

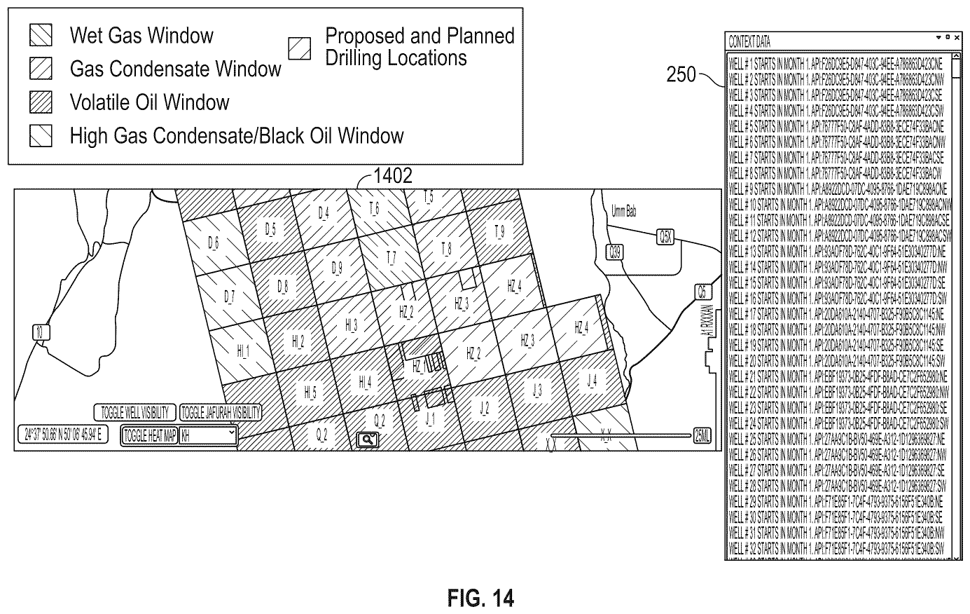

In one or more embodiments, the values of permeability and net pay or deliverability are aggregated over the block (e.g., an average). Herein, the terms “deliverability” and “deliverability magnitude” may be interchanged, where the use of “magnitude” is intended to simply emphasize that the relative value (higher, lower, etc.) of deliverability is important when making comparisons across blocks. FIG. 13 depicts the determined deliverability magnitude of each block in the plurality of blocks as a deliverability map. As stated, in one or more embodiments, the intelligent field development system (200) determines new well (or well pad) locations by scheduling wells to become operational in the blocks with the highest deliverability magnitude subject to any constraints. FIG. 14 depicts an example of a proposed wellsite schedule for the region of interest and deliverability map depicted in FIG. 13. In particular, FIG. 14 depicts a placement map (1402) where each block is categorized by a fluid type vintage similar to FIG. 6. In one or more embodiments, categorizations used in the placement map (1402) include a wet gas window, a gas condensate window, a volatile oil window, and a high gas condensate/black oil window. Further, the placement map (1402) indicates the location of proposed and scheduled drilling locations according to the proposed wellsite schedule (250) determined by the intelligent field development system (200). FIG. 14 further depicts the proposed wellsite schedule (250) as a text-based context menu. The proposed wellsite schedule (250) indicates the proposed wells, their name and location, and the relative time to drilling/producing the well. In one or more embodiments, the deliverability map of FIG. 13 and the placement map (1402) and proposed wellsite schedule (250) of FIG. 14 are displayed to a user through the user interface (202). In other embodiments, the proposed wellsite schedule (250) is output to a user.

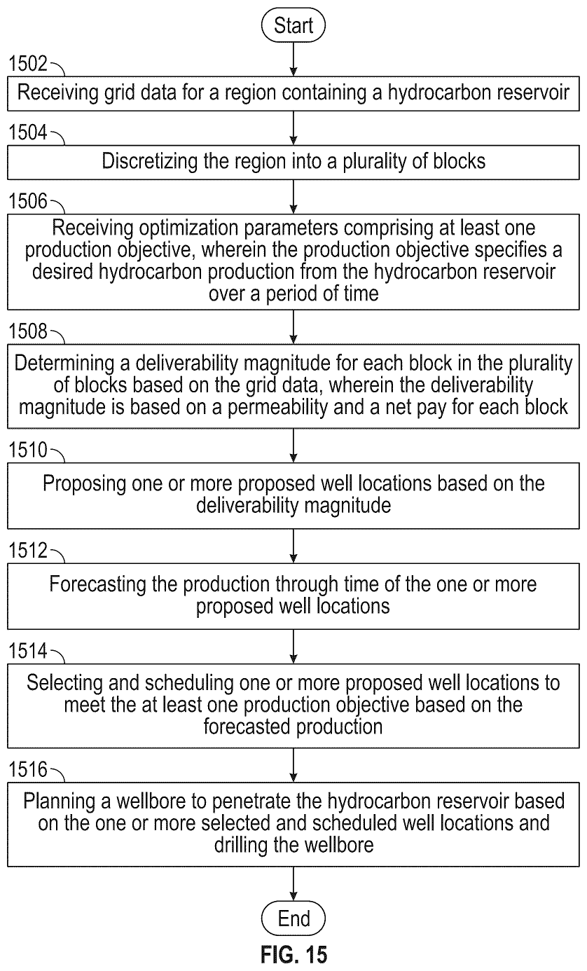

FIG. 15 depicts the processes and steps taken by the intelligent well development system (200) in accordance with one or more embodiments. In Block 1502, grid data for a region of interest containing a hydrocarbon reservoir is received. The grid data may include subsurface property distributions. In one or more embodiments, the grid data is stored in a zmap format. In Block 1504, the region is discretized into a plurality of blocks. In one or more embodiments, grid data is aggregated at the block level. In Block 1506, optimization parameters are received from a user. The optimization parameters include at least one production objective, where the production objective specifies a desired (or target) hydrocarbon production from the hydrocarbon reservoir over a period of time. In some embodiments, the optimization parameters further include at least one constraint. In Block 1508, a deliverability magnitude is determined for each block in the plurality of blocks based on the grid data. In one or more embodiments, the deliverability is determined as the product of the permeability and net pay for each block, where permeability and net pay are given, or can be calculated from, the grid data at, at least, the block level. In Block 1510, one or more well locations are proposed based on the deliverability magnitude. In one or more embodiments, wells are prioritized to be placed within blocks with the highest deliverability magnitude. That is, proposed well locations correspond with the blocks with the highest deliverability magnitude. In Block 1512, for each proposed well location, the production through time of the well is forecasted. Thus, in the event of production decline, or forecasted production decline, additional wells may be proposed in order to meet the production objective.

In Block 1514, the proposed well locations are selected and scheduled as to meet the production objective through time based on the forecasted production of the proposed wells. That is, once prioritized well locations have been determined (proposed well locations), the intelligent field development system (200) further determines a date by which each proposed well is required to become operational (and therefore producing) in order to meet the production objective through time. In particular, the selection and scheduling of the proposed wells takes into account declining production (determined through forecasting) of any current wells associated with the region of interest and the proposed wells. Thus, the selected well locations and schedule are designed by the intelligent field development system (200) to meet the specified production objective throughout the entire time period for which the production objective is specified. In Block 1516, a wellbore is planned to penetrate the hydrocarbon reservoir based on the selected and scheduled well locations. That is, a plan is established to drill a well at a selected well location according to the scheduler determined by the intelligent field development system (200). Further, in Block 1516, the wellbore is drilled according to the plan. In one or more embodiments, the wellbore plan is developed using a wellbore planning system (150) and the wellbore is drilled using drilling equipment configured at a wellsite (100).

Advantages of the intelligent field development system (200) may include the following. In one or more embodiments, the intelligent field development system (200) mitigates the difficulties in field production estimation and planning by using user defined type curves or physics-based models and an optimizing the placement of wells (or well pads) in user defined locations. This is accomplished because the intelligent field development system (200) accepts field production targets (i.e., production objectives) and determines the placement and scheduling of wells based on deliverability magnitude (i.e., location based permeability times net pay) and forecasts these wells through time to estimate their cumulative production such that production targets are met. The intelligent field development system (100) iteratively proposes, forecasts, and schedules wells so that all production targets are satisfied throughout the entire period that the production targets are defined. In one or more embodiments, the result of the intelligent field development system is a list of optimized well locations and relative time to drill these wells (i.e., a proposed wellsite schedule). As such, human intervention in the selection and scheduling of well sites is reduced. Another advantage of the intelligent field development system (200) disclosed herein is that it does not rely on finite difference simulation approaches to model well production performance. Further, the intelligent field development system (200) does not rely on a simulators ability to output adjoints which are used to calculate gradients for optimization purposes.

As discussed, in one or more embodiments, historical production data may be used by one or more machine-learned models to model and predict various quantities such as gas production rate, water production rate, etc. Machine-learned model types may include, but are not limited to, neural networks, random forests, generalized linear models, and Bayesian regression. Machine-learned model types are usually associated with additional “hyperparameters” which further describe the model. For example, hyperparameters providing further detail about a neural network may include, but are not limited to, the number of layers in the neural network, choice of activation functions, inclusion of batch normalization layers, and regularization strength. Commonly, in the literature, the selection of hyperparameter surrounding a model is referred to as selecting the model “architecture”. Consequently, in many circumstances, a machine-learned model may be specified by indicating its type and associated hyperparameters.

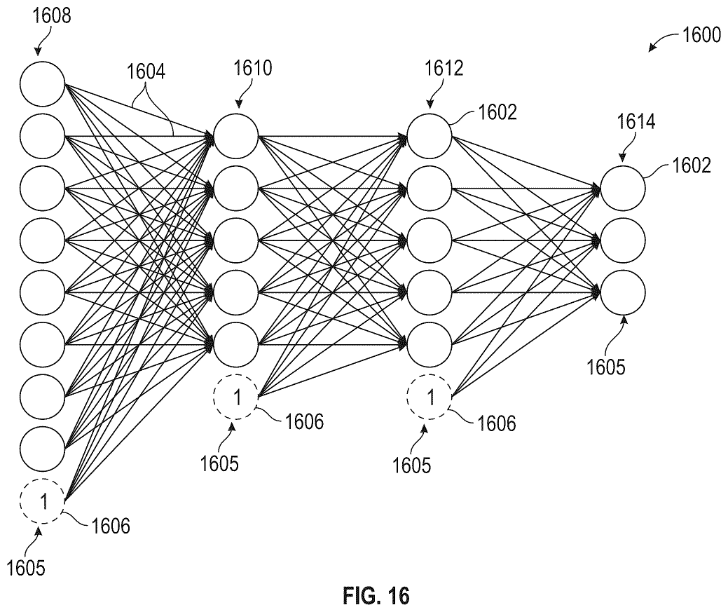

In one or more embodiments, the machine-learned model type of the machine-learned models used in the intelligent field development system (200) is a neural network. A diagram of a neural network is shown in FIG. 16. At a high level, a neural network (1600) may be graphically depicted as being composed of nodes (1602), where here any circle represents a node, and edges (1604), shown here as directed lines. The nodes (1602) may be grouped to form layers (1605). FIG. 16 displays four layers (1608, 1610, 1612, 1614) of nodes (1602) where the nodes (1602) are grouped into columns, however, the grouping need not be as shown in FIG. 16. The edges (1604) connect the nodes (1602). Edges (1604) may connect, or not connect, to any node(s) (1602) regardless of which layer (1605) the node(s) (1602) is in. That is, the nodes (1602) may be sparsely and residually connected. A neural network (1600) will have at least two layers (1605), where the first layer (1608) is considered the “input layer” and the last layer (1614) is the “output layer”. Any intermediate layer (1610, 1612) is usually described as a “hidden layer”. A neural network (1600) may have zero or more hidden layers (1610, 1612) and a neural network (1600) with at least one hidden layer (1610, 1612) may be described as a “deep” neural network or as a “deep learning method.” In general, a neural network (1600) may have more than one node (1602) in the output layer (1614). In this case the neural network (1600) may be referred to as a “multi-target” or “multi-output” network.

Nodes (1602) and edges (1604) carry additional associations. Namely, every edge is associated with a numerical value. The edge numerical values, or even the edges (1604) themselves, are often referred to as “weights” or “parameters”. While training a neural network (1600), numerical values are assigned to each edge (1604). Additionally, every node (1602) is associated with a numerical variable and an activation function. Activation functions are not limited to any functional class, but traditionally follow the form

$$A = f ( {\sum }_{i ∈ ( incoming )} [ {( node value )}_{i} {( edge value )}_{i} ] ) ,$$

where i is an index that spans the set of “incoming” nodes (1602) and edges (1604) and ƒ is a user-defined function. Incoming nodes (1602) are those that, when viewed as a graph (as in FIG. 16), have directed arrows that point to the node (1602) where the numerical value is being computed. Some functions for ƒ may include the linear function ƒ(x)=x, sigmoid function

$$f ( x ) = \frac{1}{1 + {e}^{- x}} ,$$

and rectified linear unit function ƒ(x)=max(0, x), however, many additional functions are commonly employed. Every node (1602) in a neural network (1600) may have a different associated activation function. Often, as a shorthand, activation functions are described by the function ƒ by which it is composed. That is, an activation function composed of a linear function ƒ may simply be referred to as a linear activation function without undue ambiguity.

When the neural network (1600) receives an input, the input is propagated through the network according to the activation functions and incoming node (1602) values and edge (1604) values to compute a value for each node (1602). That is, the numerical value for each node (1602) may change for each received input. Occasionally, nodes (1602) are assigned fixed numerical values, such as the value of 1, that are not affected by the input or altered according to edge (1604) values and activation functions. Fixed nodes (1602) are often referred to as “biases” or “bias nodes” (1605), displayed in FIG. 16 with a dashed circle.

In some implementations, the neural network (1600) may contain specialized layers (1605), such as a normalization layer, or additional connection procedures, like concatenation. One skilled in the art will appreciate that these alterations do not exceed the scope of this disclosure.

As noted, the training procedure for the neural network (1600) comprises assigning values to the edges (1604). To begin training the edges (1604) are assigned initial values. These values may be assigned randomly, assigned according to a prescribed distribution, assigned manually, or by some other assignment mechanism. Once edge (1604) values have been initialized, the neural network (1600) may act as a function, such that it may receive inputs and produce an output. As such, at least one input is propagated through the neural network (1600) to produce an output. Generally, a training dataset is provided the neural network for training. The training dataset is composed of inputs and associated target(s), where the target(s) represent the “ground truth”, or the otherwise desired output. The neural network (1600) output is compared to the associated input data target(s). The comparison of the neural network (1600) output to the target(s) is typically performed by a so-called “loss function”; although other names for this comparison function such as “error function” and “cost function” are commonly employed. Many types of loss functions are available, such as the mean-squared-error function, however, the general characteristic of a loss function is that the loss function provides a numerical evaluation of the similarity between the neural network (1600) output and the associated target(s). The loss function may also be constructed to impose additional constraints on the values assumed by the edges (1604), for example, by adding a penalty term, which may be physics-based, or a regularization term. Generally, the goal of a training procedure is to alter the edge (1604) values to promote similarity between the neural network (1600) output and associated target(s) over the data set. Thus, the loss function is used to guide changes made to the edge (1604) values, typically through a process called “backpropagation”.

While a full review of the backpropagation process exceeds the scope of this disclosure, a brief summary is provided. Backpropagation consists of computing the gradient of the loss function over the edge (1604) values. The gradient indicates the direction of change in the edge (1604) values that results in the greatest change to the loss function. Because the gradient is local to the current edge (1604) values, the edge (1604) values are typically updated by a “step” in the direction indicated by the gradient. The step size is often referred to as the “learning rate” and need not remain fixed during the training process. Additionally, the step size and direction may be informed by previously seen edge (1604) values or previously computed gradients. Such methods for determining the step direction are usually referred to as “momentum” based methods.

Once the edge (1604) values have been updated, or altered from their initial values, through a backpropagation step, the neural network (1600) will likely produce different outputs. Thus, the procedure of propagating at least one input through the neural network (1600), comparing the neural network (1600) output with the associated target(s) with a loss function, computing the gradient of the loss function with respect to the edge (1604) values, and updating the edge (1604) values with a step guided by the gradient, is repeated until a termination criterion is reached. Common termination criteria are: reaching a fixed number of edge (1604) updates, otherwise known as an iteration counter; a diminishing learning rate; noting no appreciable change in the loss function between iterations; reaching a specified performance metric as evaluated on the data or a separate hold-out dataset. Once the termination criterion is satisfied, and the edge (1604) values are no longer intended to be altered, the neural network (1600) is said to be “trained.”

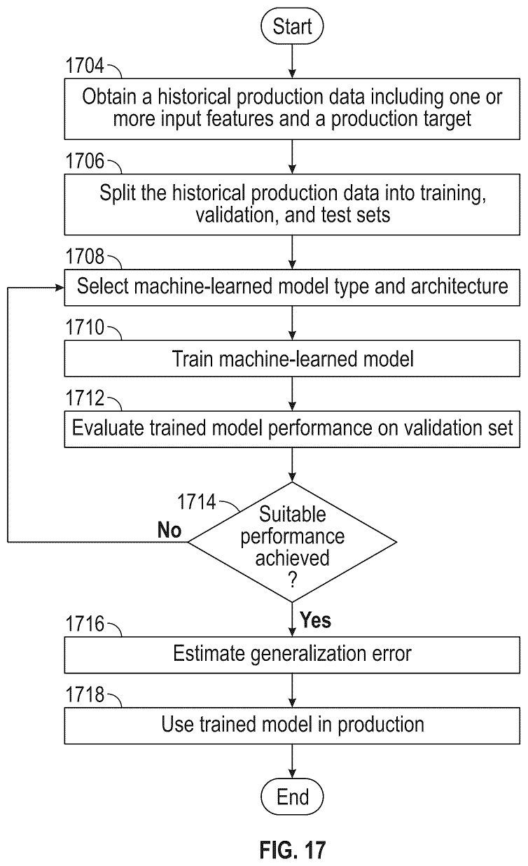

FIG. 17 depicts the general process of selecting and training a machine-learned model, in accordance with one or more embodiments. The process shown in FIG. 17 may be applied to train any of the machine-learned models used by the intelligent field development system (200).

To start, as shown in Block 1704, historical production data for one or more wells of the oil and gas field is received. The historical data set consists of input (i.e., features) and target pairs. In one or more embodiments, the input consists of well operational parameters and any data collected from field devices disposed throughout the oil and gas field (e.g., temperature sensors, pressure sensors, etc.) and the associated target is a measure production rate (e.g., gas flow rate as measured by a multiphase flow meter). In some embodiments, multiple targets are considered simultaneously (e.g., gas flow rate, condensate flow rate, and water production).

In other words, in general, the historical production data consists of the expected input and desired output for the machine-learned models. In one or more embodiments, the historical production data is preprocessed before being using to train, validate, and test the machine-learned models. Preprocessing, at a minimum, comprises altering the historical production data so that it is suitable for use with machine-learned models. For example, numericalizing categorical data (e.g., the process variable data describing the binary state of valves) or removing data entries with missing values. Other typical preprocessing methods are normalization and imputation. In these cases, information surrounding the preprocessing steps is saved for potential later use. For example, if normalization is performed then a computed mean vector and variance vector are retained. This allows future input data to be preprocessed identically. Values computed and retained during preprocessing are referred to herein as preprocessing parameters. One with ordinary skill in the art will recognize that a myriad of preprocessing methods beyond numericalization, removal of data entries with missing values, normalization, and imputation exist. Descriptions of a select few preprocessing methods herein do not impose a limitation on the preprocessing steps encompassed by this disclosure.

Returning to FIG. 17, as shown in Block 1706, the historical production data is split into training, validation, and test sets. In some embodiments, the validation and test set may be the same such that the data is effectively only split into two distinct sets. In some instances, Block 1706 may be performed before preprocessing. In this case, it is common to determine the preprocessing parameters, if any, using the training set and then to apply these parameters to the validation and test sets.

In Block 1708, a machine-learned model type and associated architecture are selected. In one or more embodiments, various machine-learned model types and architectures are predefined in a list and the subsequent processes of FIG. 17 may be applied to each machine-learned model type and architecture pairing in order to discover the pairing with the best performance. Once the machine-learned model type and hyperparameters have been selected, the machine-learned model is trained using the training set of the historical data set according to Block 1710. Common training techniques, such as early stopping, adaptive or scheduled learning rates, and cross-validation may be used during training without departing from the scope of this disclosure.

During training, or once trained, the performance of the trained machine-learned model is evaluated using the validation set as depicted in Block 1712. Recall, that in some instances, the validation set and test set are the same. Generally, performance is measured using a function which compares the predictions of the trained machine-learned model to the given targets. A commonly used comparison function is the mean-squared-error function, which quantifies the difference between the predicted value and the actual value when the predicted value is continuous, however, one with ordinary skill in the art will appreciate that many more comparison functions exist and may be used without limiting the scope of the present disclosure.

Block 1714 represents a decision: if the trained machine-learned model performance, as measured by a comparison function on the validation set (Block 1712), is not suitable, the machine-learned model architecture may be altered (i.e., return to Block 1708) and the training process is repeated. There are many mays to alter the machine-learned model architecture in search of suitable trained machine-learned model performance. These include, but are not limited to: selecting a new architecture from a previously defined set; randomly perturbing or randomly selecting new hyperparameters; using a grid search over the available hyperparameters; and intelligently altering hyperparameters based on the observed performance of previous models (e.g., a Bayesian hyperparameter search). Once suitable performance is achieved, the training procedure is complete and the generalization error of the trained machine-learned model(s) is estimated according to Block 1716.

Generalization error is an indication of the trained machine-learned model's performance on new, or un-seen data. Typically, the generalization error is estimated using the comparison function, as previously described, using the historical data set that was partitioned into the test set.

As depicted in Block 1718, the trained machine-learned model(s) is used “in production”-which means the trained machine-learned model(s) is used to process a received input without having a paired target for comparison (i.e., the trained machine-learned model is made available to and used by other components of the intelligent field development system (200). For example, the trained machine-learned models may be used to produce feature importance rankings. It is emphasized that the inputs received in the production setting, as well as for the validation and test sets, are preprocessed identically to the historical production data if preprocessing was applied before training.

While the various blocks in FIG. 17 are presented and described sequentially, one of ordinary skill in the art will appreciate that some or all of the blocks may be executed in different orders, may be combined or omitted, and some or all of the blocks may be executed in parallel. Furthermore, the blocks may be performed actively or passively.

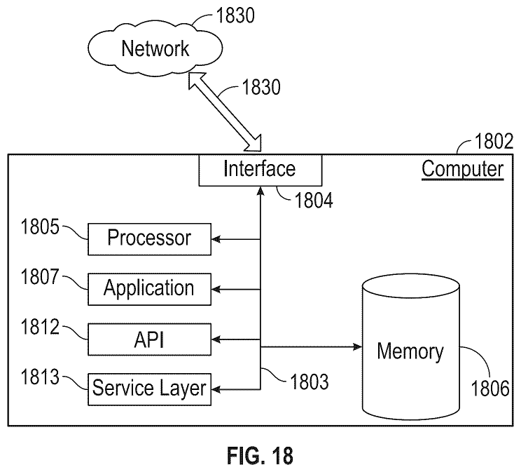

Embodiments disclosed herein may be implemented on a computer system, or, in some instances, the intelligent field development system (200) may itself be considered a computer system. FIG. 18 is a block diagram of a computer system (1802) used to provide computational functionalities associated with described algorithms, methods, functions, processes, flows, and procedures as described in the instant disclosure, according to one or more embodiments. The illustrated computer (1802) is intended to encompass any computing device such as a server, desktop computer, laptop/notebook computer, wireless data port, smart phone, personal data assistant (PDA), tablet computing device, one or more processors within these devices, or any other suitable processing device such as an edge computing device, including both physical or virtual instances (or both) of the computing device. An edge computing device is a dedicated computing device that is, typically, physically adjacent to the process or control with which it interacts. For example, the machine-learned model (429) may be implemented on an edge computing device. Additionally, the computer (1802) may include a computer that includes an input device, such as a keypad, keyboard, touch screen, or other device that can accept user information, and an output device that conveys information associated with the operation of the computer (1802), including digital data, visual, or audio information (or a combination of information), or a GUI.

The computer (1802) can serve in a role as a client, network component, a server, a database or other persistency, or any other component (or a combination of roles) of a computer system for performing the subject matter described in the instant disclosure. In some implementations, one or more components of the computer (1802) may be configured to operate within environments, including cloud-computing-based, local, global, or other environment (or a combination of environments).

At a high level, the computer (1802) is an electronic computing device operable to receive, transmit, process, store, or manage data and information associated with the described subject matter. According to some implementations, the computer (1802) may also include or be communicably coupled with an application server, e-mail server, web server, caching server, streaming data server, business intelligence (BI) server, or other server (or a combination of servers).

The computer (1802) can receive requests over network (1830) from a client application (for example, executing on another computer (1802) and responding to the received requests by processing the said requests in an appropriate software application. In addition, requests may also be sent to the computer (1802) from internal users (for example, from a command console or by other appropriate access method), external or third-parties, other automated applications, as well as any other appropriate entities, individuals, systems, or computers.

Each of the components of the computer (1802) can communicate using a system bus (1803). In some implementations, any or all of the components of the computer (1802), both hardware or software (or a combination of hardware and software), may interface with each other or the interface (1804) (or a combination of both) over the system bus (1803) using an application programming interface (API) (1812) or a service layer (1813) (or a combination of the API (1812) and service layer (1813). The API (1812) may include specifications for routines, data structures, and object classes. The API (1812) may be either computer-language independent or dependent and refer to a complete interface, a single function, or even a set of APIs. The service layer (1813) provides software services to the computer (1802) or other components (whether or not illustrated) that are communicably coupled to the computer (1802). The functionality of the computer (1802) may be accessible for all service consumers using this service layer. Software services, such as those provided by the service layer (1813), provide reusable, defined business functionalities through a defined interface. For example, the interface may be software written in JAVA, C++, or other suitable language providing data in extensible markup language (XML) format or another suitable format. While illustrated as an integrated component of the computer (1802), alternative implementations may illustrate the API (1812) or the service layer (1813) as stand-alone components in relation to other components of the computer (1802) or other components (whether or not illustrated) that are communicably coupled to the computer (1802). Moreover, any or all parts of the API (1812) or the service layer (1813) may be implemented as child or sub-modules of another software module, enterprise application, or hardware module without departing from the scope of this disclosure.

The computer (1802) includes an interface (1804). Although illustrated as a single interface (1804) in FIG. 18, two or more interfaces (1804) may be used according to particular needs, desires, or particular implementations of the computer (1802). The interface (1804) is used by the computer (1802) for communicating with other systems in a distributed environment that are connected to the network (1830). Generally, the interface (1804) includes logic encoded in software or hardware (or a combination of software and hardware) and operable to communicate with the network (1830). More specifically, the interface (1804) may include software supporting one or more communication protocols associated with communications such that the network (1830) or interface's hardware is operable to communicate physical signals within and outside of the illustrated computer (1802).

The computer (1802) includes at least one computer processor (1805). Although illustrated as a single computer processor (1805) in FIG. 18, two or more processors may be used according to particular needs, desires, or particular implementations of the computer (1802). Generally, the computer processor (1805) executes instructions and manipulates data to perform the operations of the computer (1802) and any algorithms, methods, functions, processes, flows, and procedures as described in the instant disclosure.

The computer (1802) also includes a memory (1806) that holds data for the computer (1802) or other components (or a combination of both) that can be connected to the network (1830). The memory may be a non-transitory computer readable medium. For example, memory (1806) can be a database storing data consistent with this disclosure. Although illustrated as a single memory (1806) in FIG. 18, two or more memories may be used according to particular needs, desires, or particular implementations of the computer (1802) and the described functionality. While memory (1806) is illustrated as an integral component of the computer (1802), in alternative implementations, memory (1806) can be external to the computer (1802).

The application (1807) is an algorithmic software engine providing functionality according to particular needs, desires, or particular implementations of the computer (1802), particularly with respect to functionality described in this disclosure. For example, application (1807) can serve as one or more components, modules, applications, etc. Further, although illustrated as a single application (1807), the application (1807) may be implemented as multiple applications (1807) on the computer (1802). In addition, although illustrated as integral to the computer (1802), in alternative implementations, the application (1807) can be external to the computer (1802).

There may be any number of computers (1802) associated with, or external to, a computer system containing computer (1802), wherein each computer (1802) communicates over network (1830). Further, the term “client,” “user,” and other appropriate terminology may be used interchangeably as appropriate without departing from the scope of this disclosure. Moreover, this disclosure contemplates that many users may use one computer (1802), or that one user may use multiple computers (1802).

Although only a few example embodiments have been described in detail above, those skilled in the art will readily appreciate that many modifications are possible in the example embodiments without materially departing from this invention. In addition, many modifications will be appreciated by those skilled in the art to adapt a particular instrument, situation, or material to embodiments of the disclosure without departing from the essential scope thereof. Accordingly, all such modifications are intended to be included within the scope of this disclosure as defined in the following claims. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

Furthermore, any apparatus described herein may be free of any component not expressly recited or disclosed herein. Any method or system may lack any step not recited or disclosed herein. Likewise, the term “comprising” is considered synonymous with the term “including.” Whenever a method, composition, element or group of elements is preceded with the transitional phrase “comprising,” it is understood that we also contemplate the same composition or group of elements with transitional phrases “consisting essentially of,” “consisting of,” “selected from the group of consisting of,” or “is” preceding the recitation of the composition, element, or elements and vice versa.

What is claimed is:

1. A method to determine locations of new wells, comprising:
receiving grid data for a region containing a hydrocarbon reservoir;
discretizing the region into a plurality of blocks;
receiving optimization parameters comprising at least one production objective, wherein the production objective specifies a desired hydrocarbon production from the hydrocarbon reservoir over a period of time;
determining a deliverability magnitude for each block in the plurality of blocks based on the grid data, wherein the deliverability magnitude is based on a permeability and a net pay for each block;
proposing one or more proposed well locations based on the deliverability magnitude;
forecasting the production through time of the one or more proposed well locations; and
selecting and scheduling one or more proposed well locations to meet the at least one production objective based on the forecasted production.

2. The method of claim 1, further comprising planning a wellbore to penetrate the hydrocarbon reservoir based on the one or more selected and scheduled well locations, wherein the planned wellbore comprises a planned wellbore path.

3. The method of claim 2, further comprising drilling the wellbore guided by the planned wellbore path.

4. The method of claim 1, further comprising:
receiving historical data comprising one or more features;
training one or more machine-learned models using the historical data; and
determining a relative importance of the one or more features using the one or more trained machine-learned models.

5. The method of claim 1, wherein the optimization parameters further comprise at least one constraint, and wherein the one or more proposed well locations are selected subject to the at least one constraint.

6. The method of claim 1, further comprising:
ranking the blocks in the plurality of blocks by deliverability magnitude.

7. The method of claim 1, further comprising:
receiving a type curve; and
determining a pressure-volume-temperature (PVT) behavior for each block;
wherein the forecasted production is based on the type curve and the PVT behavior for each block.

8. The method of claim 1, further comprising:
determining a sensitivity and an uncertainty of the forecasted production.

9. An intelligent field development system, comprising:
an oil and gas field with an associated hydrocarbon reservoir;
one or more computer processors configured to:
receive grid data for the oil and gas field;
discretize the region into a plurality of blocks;
receive optimization parameters comprising at least one production objective, wherein the production objective specifies a desired hydrocarbon production from the hydrocarbon reservoir over a period of time;
determine a deliverability magnitude for each block in the plurality of blocks based on the grid data, wherein the deliverability magnitude is based on a permeability and a net pay for each block;
propose one or more proposed well locations based on the deliverability magnitude;
forecast the production through time of the one or more proposed well locations; and
select and schedule one or more proposed well locations to meet the at least one production objective based on the forecasted production.

10. The system of claim 9, further comprising a wellbore planning system configured to plan a wellbore to penetrate the hydrocarbon reservoir based on the one or more selected and scheduled well locations, wherein the planned wellbore comprises a planned wellbore path.

11. The system of claim 10, further comprising a drilling system configured to drill the wellbore guided by the planned wellbore path.

12. The system of claim 9, further comprising a machine-learning suite configured to:
receive historical data comprising one or more features;
train one or more machine-learned models using the historical data; and
determine a relative importance of the one or more features using the one or more trained machine-learned models.

13. The system of claim 9, wherein the optimization parameters further comprise at least one constraint, and wherein the one or more proposed well locations are selected subject to the at least one constraint.

14. The system of claim 9, wherein the one or more computer processors is further configured to rank the blocks in the plurality of blocks by deliverability magnitude.

15. The system of claim 9, wherein the one or more computer processors is further configured to:
receive a type curve; and
determine a pressure-volume-temperature (PVT) behavior for each block;
wherein the forecasted production is based on the type curve and the PVT behavior for each block.

16. The system of claim 9, further comprising an uncertainty module configured to determine a sensitivity and an uncertainty of the forecasted production.

17. A non-transitory computer readable medium storing instructions executable by a computer processor, the instructions comprising functionality for:
receiving grid data for a region containing a hydrocarbon reservoir;
discretizing the region into a plurality of blocks;
receiving optimization parameters comprising at least one production objective, wherein the production objective specifies a desired hydrocarbon production from the hydrocarbon reservoir over a period of time;
determining a deliverability magnitude for each block in the plurality of blocks based on the grid data, wherein the deliverability magnitude is based on a permeability and a net pay for each block;
proposing one or more proposed well locations based on the deliverability magnitude;
forecasting the production through time of the one or more proposed well locations; and
selecting and scheduling one or more proposed well locations to meet the at least one production objective based on the forecasted production.

18. The non-transitory computer readable medium of claim 17, wherein the instructions further comprise functionality for planning a wellbore to penetrate the hydrocarbon reservoir based on the one or more selected and scheduled well locations, wherein the planned wellbore comprises a planned wellbore path.

19. The non-transitory computer readable medium of claim 17, wherein the instructions further comprise functionality for:
receiving a type curve; and
determining a pressure-volume-temperature (PVT) behavior for each block;
wherein the forecasted production is based on the type curve and the PVT behavior for each block.

20. The non-transitory computer readable medium of claim 17, wherein the optimization parameters further comprise at least one constraint, and wherein the one or more proposed well locations are selected subject to the at least one constraint.
